(19) United States
(12) Patent Application Publication
(10) Pub. No.: US 2004/0207011 A1
(43) Pub. Date: Oct. 21, 2004

(54) Semiconductor device, semiconductor storage device and production methods therefor

(76) Inventors: Hiroshi Iwata, Ikoma-gun (JP); Akihide Shibata, Nara-shi (JP); Kotaro Kataoka, Tenri-shi (JP); Seizo Kakimoto, Shiki-gun (JP)

Correspondence Address: BIRCH STEWART KOLASCH & BIRCH, PO BOX 747, FALLS CHURCH, VA, 22040-0747, US

(21) Appl. No.: 10/484,078

(22) PCT Filed: Jul. 18, 2002
(86) PCT No.: PCT/JP02/07284

(30) Foreign Application Priority Data
Jul. 19, 2001 (JP) 2001-219809
Sep. 13, 2001 (JP) 2001-278117

(51) Int. Cl. H01L 29/76

(52) U.S. Cl. 257/341

(57) ABSTRACT

A gate electrode sidewall conductive film 120 is formed via a gate electrode sidewall insulation film 119 on a sidewall of a gate electrode 118. By properly removing this gate electrode sidewall conductive film 120 by anisotropic etching that has selectivity to the gate electrode sidewall insulation film 119, isolation between a source region and a drain region and formation of local interconnections by the gate electrode sidewall conductive film 120 are concurrently achieved. Further, the gate electrode 118 is also properly removed by etching that has selectivity to the gate electrode sidewall insulation film 119, and therefore, the gate electrode interconnection is concurrently formed. Through the above process, there can be provided an SRAM device, which is allowed to have high integration by shrinking the memory cell area with simplified interconnections.

### TECHNICAL FIELD

The present invention relates to a semiconductor device, a semiconductor storage device and manufacturing methods therefor.

The present invention relates more precisely to static random access memory (SRAM) that has a stack type diffusion region and a manufacturing method therefor.

The present invention relates also to a semiconductor device, a manufacturing method therefor, a static random access memory device and a portable electronic equipment. In concrete, the invention relates to a semiconductor device that includes a dynamic threshold transistor, a manufacturing method therefor, a static random access memory device and a portable electronic equipment, which are provided with this semiconductor device.

### BACKGROUND ART

As a kind of random access memory (RAM), there is an SRAM that can operate at high speed and requires no refresh operation. FIGS. 20 and 21 show one example of the prior art SRAM cell. FIGS. 20 and 21 are plan views of the SRAM cell. FIG. 20 shows the understructure of a first layer metal interconnection, and FIG. 21 shows the structures of metal interconnections of a second layer and a third layer. In the figures, the reference numeral 911 denotes a silicon substrate active region (region that is not the element isolation region), 912 denotes polysilicon interconnections, 913 denotes first layer metal interconnections, 914 denotes a contact hole (hole that connects the active region or the polysilicon interconnection with the first layer metal interconnection), 915 denotes a contact hole and first via hole (hole that connects the first layer metal interconnection with a second layer metal interconnection), 916 denotes a contact hole and first via hole and second via hole (hole that connects the second layer metal interconnection with a third layer metal interconnection), 917 denotes bit lines, 918 denotes a grounding line, and 919 denotes a word line. It is to be noted that the polysilicon interconnections 912 constitute gate electrodes, the bit lines 917 are constructed of the second layer metal interconnections, and the grounding line 918 and the word line 919 are constructed of the third layer metal interconnections. The reference numerals N1 through N4 represent n-type MOSFET's, and the reference numerals P1 and P2 represent p-type MOSFET's. A pair of N1 and P1 and a pair of N2 and P2 constitute inverter circuits respectively, and these two inverter circuits constitute a flip-flop circuit capable of storing information of one bit. The reference numerals N3 and N4 denote transfer gate transistors. The dashed lines 920 represent a unit memory cell. In the aforementioned example, a structure (contact holes, metal interconnections and so on) for fixing the potential of the well region is not shown.

With the aforementioned construction, the SRAM, which has the flip-flop circuit, is therefore able to retain the storage without refresh operation so long as a power is supplied. Moreover, during read operation, electric charges are supplied directly from a power line to the bit line through the transistor (or electric charges are discharged directly from the bit line to the power line), and therefore, high-speed operation can be achieved.

However, the SRAM has a problem that it has a large memory cell area since the number of elements constituting the memory cell is greater than that of DRAM (Dynamic Random Access Memory). One factor disturbing the shrinkage of the memory cell area of the SRAM is that margins of interconnections become increased since the interconnections in the memory cell are provided by upper metal interconnections through contact holes. In the aforementioned example, ten contact holes are needed per unit memory cell.

The present invention is accomplished to alleviate the aforementioned problems and intended to provide an SRAM device allowed to have a high integration by shrinking the memory cell area with simplified interconnections.

Moreover, it is most effective to lower the power voltage in order to reduce power consumption in a CMOS (Complementary MOS) circuit that employs a MOSFET (Metal Oxide Semiconductor Field Effect Transistor). However, if the power voltage is simply lowered, then the drive current of the MOSFET is reduced, and the operating speed of the circuit becomes slow. It is known that this phenomenon becomes significant when the power voltage becomes equal to or lower than three times of the threshold value of the transistor. It is proper to lower the threshold value in order to prevent this phenomenon, but the adoption of the measure is to cause a problem that a leak current in the off-stage of the MOSFET increases. Therefore, the lower limit of the threshold value is defined within a range in which the above-mentioned problem does not occur. Since the lower limit of the threshold value corresponds to the lower limit of the power voltage, the limit of power consumption reduction is defined.

Conventionally, in order to alleviate the aforementioned problem, there has been proposed a dynamic threshold transistor employing a bulk substrate (Japanese Patent Application Laid Open No. H10-22462, Novel Bulk Threshold Voltage MOSFET (B-DTMOS) with Advanced Isolation (SITOS) and Gate to Shallow Well Contact (SSS-C) Processes for Ultra Low Power Dual Gate CMOS, H. Kotaki et al., IEDM Tech. Dig., p459, 1996). The dynamic threshold transistor, which has its effective threshold value lowered when turned on, therefore has a feature that a high drive current can be obtained at a low power voltage. The reason why the effective threshold value of the dynamic threshold transistor is lowered when it is turned on is that the gate electrode and the well region are electrically short-circuited.

The principle of operation of an n-type dynamic threshold transistor will be described below. It is to be noted that a p-type dynamic threshold transistor similarly operates by polarity inversion. In the n-type MOSFET, when the potential of the gate electrode has low level (in the off stage), the potential of the p-type well region also has low level, and the effective threshold value is not different from that of the normal MOSFET. Therefore, the off-state current value (off-leak) is the same as in the case of the normal MOSFET.

When the potential of the gate electrode has high level (in the on-stage), the potential of the p-type well region also has high level, the effective threshold value is lowered by a substrate bias effect, and the drive current is increased in comparison with the case of the normal MOSFET. Therefore, a large drive current can be obtained with a low leak current maintained at a low power voltage. Therefore, a CMOS circuit of low power consumption is achieved by low voltage driving.

However, the dynamic threshold transistor of the aforementioned prior art has had a problem that a gate current has disadvantageously flowed in the on-stage due to the electrical connection of the gate electrode with the well region, the problem being inherent in the dynamic threshold transistor.

The influence of the gate current is considered with reference to FIGS. 22 and 23. FIG. 22 is a graph showing the characteristics of the drain current (Id) and the gate current (Ig) with respect to the gate voltage (Vg) of the n-channel type dynamic threshold transistor. It can be understood that the gate current Ig exponentially increases as the gate voltage Vg increases. In the example of the n-channel type dynamic threshold transistor shown in FIG. 22, the gate current Ig when the gate voltage Vg is 0.5V is equivalent to the off-state current (Id when Vg=0 V).

FIG. 23 is a circuit diagram of a CMOS circuit constructed of a two-stage inverter circuit. Inverter circuits 1 and 2 are connected between a power line (VDD) and a grounding line (GND). The inverter circuits 1 and 2 are constructed of n-channel type dynamic threshold transistors 11 and 13 and p-channel type dynamic threshold transistors 12 and 14, respectively. An input terminal IN is provided for the input of the inverter circuit 1, the output of the inverter circuit 1 is connected to the input of inverter circuit 2, and an output terminal OUT is provided for the output of the inverter circuit 2.

In this case, it is considered the case where low level is applied to the input terminal IN. At this time, an intermediate node MID has high level, and low level is outputted to the output terminal OUT. At this time, the p-channel type dynamic threshold transistor 12 and the n-channel type dynamic threshold transistor 13 are in the on state, and the n-channel type dynamic threshold transistor 11 and the p-channel type dynamic threshold transistor 14 are in the off-state. In the n-channel type dynamic threshold transistor 11 in the off-state, an off-state current of the level indicated by A in the graph of FIG. 22 flows through the path indicated by arrow 22 in FIG. 23. On the other hand, in the n-channel type dynamic threshold transistor 13 in the on-state, a gate current of the level indicated by B in the graph of FIG. 22 flows through a path from the gate electrode toward the source electrode as indicated by arrow 23 in FIG. 23. In this case, the power voltage was set to 0.6 V. The off-state current A and the gate current B become leak currents that flow from the power line VDD to the grounding line GND through the p-channel type dynamic threshold transistor 12 in the on-state as indicated by arrow 21 in FIG. 23. In the example of FIG. 22, the level B of the gate current is one order of magnitude larger than the level A of the off-state current when the power voltage is 0.6 V. As to the cost of the p-channel type dynamic threshold transistors, an off-state current and a gate current also flow through them similarly to the case of the aforementioned n-channel type dynamic threshold transistors, and therefore, a similar leak current is generated.

The origin of the gate current is a forward junction current of the well region and the source region, and the current is proportional to the junction area. It is difficult to largely reduce the gate current by reducing this junction area from the viewpoint of designing the MOS transistor. Therefore, it has been a serious problem to reduce the leak current during the static state of the circuit in a CMOS circuit of low consumption power. Particularly, in a CMOS circuit constructed of dynamic threshold transistors, it has been a problem peculiar to the dynamic threshold transistor to reduce the leak current caused by the gate current.

Accordingly, it is an object of the present invention to provide a semiconductor device that includes a dynamic threshold transistor and is able to reduce the leak current caused by the gate current. Moreover, the problem of the present invention is to provide a semiconductor device manufacturing method capable of manufacturing such a semiconductor device as well as a static random access memory device and a portable electronic equipment, which are provided with such a semiconductor device.

### DISCLOSURE OF THE INVENTION

In order to solve the aforementioned problems, the static random access memory device of a first aspect of the invention comprises:

a semiconductor substrate that has an element isolation region and an active region;

a gate electrode provided via a gate insulation film on the semiconductor substrate;

a gate electrode sidewall insulation film provided on at least part of a sidewall of the gate electrode; and

a gate electrode sidewall conductive film that is provided on at least part of a sidewall of the gate electrode sidewall insulation film and provided over a plurality of active regions segmented by the element isolation region.

According to the above-mentioned construction, the gate electrode is provided with the gate electrode sidewall conductive film via the gate electrode sidewall insulation film, and the gate electrode sidewall conductive film is provided over the plurality of active regions segmented by the element isolation regions. That is, the gate electrode sidewall conductive film functions as local interconnections for connecting the plurality of active regions. Therefore, the interconnection pitch can be made smaller than that of the case in which the upper metal interconnections are used, and the number of contact holes can be reduced, allowing the interconnections to be simplified. Accordingly, there is provided an SRAM device that has a small cell area and high integration.

Moreover, in one embodiment of the static random access memory device of the first aspect of the invention, the semiconductor substrate is comprised of a SOI substrate.

According to the above-mentioned embodiment, the SOI substrate is employed as the semiconductor substrate, and therefore, the junction area of the source region and the drain region is reduced, and electrostatic capacity can be remarkably reduced. Accordingly, there is provided a static random access memory device of low power consumption.

Furthermore, in forming the element isolation regions, isolation between elements can be effectively achieved merely by isolating the thin silicon layer (SOI layer), and therefore, the element isolation process is facilitated.

Moreover, the static random access memory device of the second aspect of the invention comprises:

a semiconductor substrate that has an element isolation region and an active region;

a first conductive type deep well region formed in the semiconductor substrate;

a second conductive type shallow well region formed in the first conductive type deep well region;

a gate electrode provided via a gate insulation film on the semiconductor substrate;

a gate electrode sidewall insulation film provided on at least part of a sidewall of the gate electrode; and

a gate electrode sidewall conductive film that is provided on at least part of a sidewall of the gate electrode sidewall insulation film and provided over a plurality of active regions segmented by the element isolation region,

at least part of the gate electrode constituting a first conductive type dynamic threshold transistor by being electrically connected to the second conductive type shallow well region, and

the second conductive type shallow well region being electrically isolated by the element isolation region.

In the present specification, the first conductive type means the p-type or the n-type. Moreover, the second conductive type means the n-type when the first conductive type is the p-type or means the p-type when the first conductive type is the n-type.

According to the above-mentioned construction, operation and effects similar to those of the static random access memory device of the first aspect of the invention can be obtained. Furthermore, at least part of the gate electrode is electrically connected to the second conductive type shallow well region and constitutes the first conductive type dynamic threshold transistor. Moreover, the potential of the second conductive type shallow well region electrically connected to the gate electrode changes according to the potential of the gate electrode. However, the well region is electrically isolated by the element isolation region, and therefore, interference between elements can be prevented. The dynamic threshold transistor has the characteristic that it has high driving ability at a low power voltage, and accordingly, there is provided a static random access memory device that can operate at high speed while being driven by a low voltage.

Moreover, the static random access memory device of the third aspect of the invention comprises:

a semiconductor substrate that has an element isolation region and an active region;

a first conductive type deep well region formed in the semiconductor substrate;

a second conductive type shallow well region formed in the first conductive type deep well region;

a gate electrode provided via a gate insulation film on the semiconductor substrate;

a gate electrode sidewall insulation film provided on at least part of a sidewall of the gate electrode; and

a gate electrode sidewall conductive film that is provided on at least part of a sidewall of the gate electrode sidewall insulation film and provided over a plurality of active regions segmented by the element isolation region,

at least part of the gate electrode constituting a first conductive type dynamic threshold transistor by being electrically connected to the second conductive type shallow well region,

the element isolation region being comprised of a shallow element isolation region and a deep element isolation region, and

the second conductive type shallow well region being electrically isolated by the deep element isolation region.

According to the above-mentioned construction, operation and effects similar to those of the static random access memory device of the second aspect of the invention can be obtained. Furthermore, the element isolation region is constructed of the shallow element isolation region and the deep element isolation region, and the second conductive type shallow well region is electrically isolated by the deep element isolation region. In general, it is difficult to form deep element isolation regions of various widths due to the characteristic of the embedment process of the insulation film. On the other hand, although it is easy to form shallow element isolation regions of various widths, it is difficult to isolate the shallow well region every element. Therefore, by combining the shallow element isolation region with the deep element isolation region, the shallow well region can be isolated every element with a small margin, and element isolation regions of various widths can be formed.

Moreover, the static random access memory device of the fourth aspect of the invention comprises:

a SOI semiconductor substrate that has an element isolation region and an active region;

a gate electrode provided via a gate insulation film on the SOI semiconductor substrate;

a gate electrode sidewall insulation film provided on at least part of a sidewall of the gate electrode; and

a gate electrode sidewall conductive film that is provided on at least part of a sidewall of the gate electrode sidewall insulation film and provided over a plurality of active regions segmented by the element isolation region,

at least part of the gate electrode constituting a first conductive type dynamic threshold transistor by being electrically connected to the second conductive type body region of the SOI semiconductor substrate.

According to the above-mentioned construction, operation and effects similar to those of the static random access memory device of the first aspect of the invention can be obtained. Furthermore, at least part of the gate electrode is connected to the second conductive type body region and constitutes the first conductive type dynamic threshold transistor. The dynamic threshold transistor has the characteristic that it has high driving ability at a low power voltage, and accordingly, there is provided a static random access memory device that can operate at high speed while being driven at a low voltage.

Furthermore, according to the fourth aspect of the invention, which includes the dynamic threshold transistor, the potential of the body region changes according to the change in the potential of the gate electrode, and therefore, the effective electrostatic capacity is increased. However, in the present fourth aspect of the invention, the SOI substrate is employed as the substrate, and therefore, the effect of reducing the electrostatic capacity by virtue of the reduction in the junction area of the source region and the drain region due to the SOI substrate and the existence of the thick embedded oxide film is remarkable. Accordingly, there is provided a static random access memory device of low power consumption.

Furthermore, in forming the element isolation regions, isolation between elements can be effectively achieved merely by isolating the thin SOI layer, and therefore, the element isolation process is facilitated. Moreover, according to the present invention, the element isolation region is allowed to be the same as in the case where no dynamic threshold transistor is included despite the fact that the dynamic threshold transistor is included. Therefore, the element isolation region formation process is remarkably simplified. Accordingly, the manufacturing of the static random access memory device is facilitated.

Moreover, in one embodiment of the static random access memory device of the second or third aspect of the invention,

a first conductive type shallow well region is formed in the first conductive type deep well region, the deep well region and the shallow well region of the first conductive type integrally constituting a first conductive type well region,

the static random access memory device is a six-element type comprising:

two second conductive type field-effect transistors that constitute a flip-flop circuit formed on the first conductive type well region;

two first conductive type field-effect transistors that constitute a flip-flop circuit formed on the second conductive type shallow well region; and

two first conductive type field-effect transistors that serve as transfer gate transistors formed on the second conductive type shallow well region, and

only the four first conductive type field-effect transistors are the dynamic threshold transistors.

According to the above-mentioned embodiment, the two first conductive type field-effect transistors that constitute the flip-flop circuit and the two first conductive type field-effect transistors that serve as the transfer gate transistors, which require high driving ability, are the dynamic threshold transistors. On the other hand, the two second conductive type field-effect transistors that constitute the flip-flop circuit, which requires not so high driving ability, are not dynamic threshold transistors. Therefore, the two second conductive type field-effect transistors require no margin for electrically connecting the gate electrode with the shallow well region. Moreover, the first conductive type shallow well region is integrated with the first conductive type deep well region, and therefore, the margin between the shallow well regions of the first conductive type and the second conductive type can be kept small. Accordingly, there is provided an SRAM device, which can operate at high speed and has, a small cell area and high integration.

Moreover, in one embodiment of the static random access memory device, the first conductive type is n-type.

According to the above-mentioned embodiment, the n-type field-effect transistor that generally has high driving ability is provided as the dynamic threshold transistor and is used in places where high driving ability is required, and therefore, the static random access memory device can be operated at higher speed. Otherwise, a high driving power can be obtained even if the gate width of the n-channel type MOSFET is reduced, and therefore, the memory cell area can be shrunk.

Moreover, in one embodiment of the static random access memory device, the gate electrode sidewall conductive film is comprised of a polycrystalline semiconductor film.

According to the above-mentioned embodiment, the impurity diffusion speed in the polycrystalline semiconductor film is extremely greater than in the crystalline semiconductor region. Therefore, it is easy to shallow the depth of the junction between the source region and the drain region and to control the short-channel effect, and scale shrinkage can be facilitated. Accordingly, there is provided an SRAM device that has a small cell area and high integration.

Moreover, the static random access memory device manufacturing method of the fifth aspect of the invention comprises the steps of:

forming a gate insulation film on a semiconductor substrate;

forming a first conductive film on at least the gate insulation film;

forming a first conductive film pattern by processing the first conductive film into a prescribed pattern;

forming a sidewall insulation film on at least part of a sidewall of the first conductive film pattern;

forming a sidewall conductive film comprised of the second conductive film via the sidewall insulation film on a sidewall of the first conductive film pattern by depositing the second conductive film on the semiconductor substrate and etching the second conductive film; and

forming a layer that serves as a gate electrode, a layer that serves as a source region, a layer that serves as a drain region and an interconnection that is constructed of a stack type diffusion layer by processing the first conductive film pattern and the sidewall conductive film so as to remove part of the first conductive film pattern and part of the sidewall conductive film by anisotropic etching that has selectivity to the sidewall insulation film.

According to the above-mentioned fifth aspect of the invention, the sidewall conductive film constructed of the second conductive film is formed via the sidewall insulation film on the sidewall of the first conductive film pattern. By properly removing this sidewall conductive film by anisotropic etching that has selectivity to the sidewall insulation film, the isolation of the source region and the drain region and the formation of local interconnections (interconnections constructed of stack type diffusion layer) are concurrently carried out. Furthermore, the first conductive film pattern is also properly removed by the anisotropic etching that has selectivity to the sidewall insulation film, and therefore, the gate electrode interconnection is concurrently formed. Furthermore, when providing a dynamic threshold transistor, if the first conductive film pattern on the active region is removed by the anisotropic etching that has selectivity to the sidewall insulation film, then the region for electrically connecting the gate electrode with the shallow well region can be concurrently formed. Therefore, various purposes are achieved through only one-time etching process, and therefore, the manufacturing cost can be reduced by simplifying the manufacturing process of the static random access memory device.

Moreover, in order to solve the aforementioned problems, the semiconductor device of the sixth aspect of the invention comprises:

a complementary type circuit comprised of a plurality of dynamic threshold transistors in which a well region segmented every element by an element isolation region is electrically connected with a gate electrode,

the complementary type circuit comprising at least two modes of:

an active mode in which the complementary type circuit is operated at high speed; and

a standby mode in which the complementary type circuit is operated at low speed or its operation is stopped, and

when the complementary type circuit is in the standby mode, the complementary type circuit being supplied with a power voltage lower than when the complementary type circuit is in the active mode.

According to the semiconductor device of this sixth aspect of the invention, the complementary type circuit constructed of the dynamic threshold transistor has at least two operation modes of the active mode and the standby mode. Then, a sufficiently high power voltage is supplied in the active mode, and therefore, the circuit can be operated at high speed. The standby mode is effected when the circuit is in the stop state or operated at low speed, and the gate current, which becomes the principal cause of the leak current, can be remarkably restrained by giving a low power voltage. Therefore, the semiconductor device, which is constructed of the complementary type circuit of the dynamic threshold transistors, is allowed to have low power consumption with the operating speed kept at high speed.

In the semiconductor device of one embodiment, when the complementary type circuit is in the standby mode, the dynamic threshold transistor that constitutes the complementary type circuit has a gate current value that is not greater than an off-state current value of the dynamic threshold transistor.

According to the semiconductor device of this embodiment, the leak current of the complementary type circuit can be sufficiently reduced down to the magnitude defined by the off-state current of the dynamic threshold transistor. That is, the effect of the semiconductor device of the sixth aspect of the invention can be produced to a maximum.

In the semiconductor device of one embodiment, the complementary type circuit is divided into a plurality of basic circuit blocks, and the basic circuit blocks can be independently put into the active mode or the standby mode.

According to the semiconductor device of this embodiment, the complementary type circuit constructed of the dynamic threshold transistors is divided into a plurality of basic circuit blocks, and each of them can be independently put into the active mode or the standby mode. Therefore, the leak current can be reduced by putting only the basic circuit block required to be operated at high speed into the active mode and putting the other basic circuit blocks into the standby mode. Therefore, further reduced power consumption can be achieved with the operating speed of the circuit kept at high speed.

Moreover, the semiconductor device of the seventh aspect of the invention comprises:

a semiconductor substrate;

an element isolation region;

deep well regions of a first conductive type and a second conductive type, the regions being formed in the semiconductor substrate;

shallow well regions of the second conductive type and the first conductive type, the regions being formed respectively in the deep well regions of the first conductive type and the second conductive type; and

a plurality of gate electrodes formed via a gate insulation film on the shallow well regions of the second conductive type and the first conductive type,

the plurality of gate electrodes being electrically connected to the shallow well region of the second conductive type or the first conductive type, constituting dynamic threshold transistors of the first conductive type and the second conductive type, respectively,

the shallow well regions of the second conductive type and the first conductive type being electrically isolated by the element isolation region every one of the dynamic threshold transistors,

the second conductive type shallow well region having therein a low impurity concentration layer of the second conductive type and a high impurity concentration layer of the second conductive type, which are formed successively in a depthwise direction from an interface side with the gate insulation film,

the first conductive type shallow well region having therein a low impurity concentration layer of the first conductive type and a high impurity concentration layer of the first conductive type, which are formed successively in the depthwise direction from the interface side with the gate insulation film,

the low impurity concentration layers of the second conductive type and the first conductive type having a thickness of not greater than 40 nm, and

the dynamic threshold transistors of the first conductive type and the second conductive type constituting a complementary type circuit.

According to the semiconductor device of this seventh aspect of the invention, the complementary type circuit is constructed of the dynamic threshold transistors of the first conductive type and the second conductive type. Then, the layer of low impurity concentration of the second conductive type (first conductive type) and the high impurity concentration layer of the second conductive type (first conductive type) are successively formed in the depthwise direction from the interface side with the gate insulating film in the shallow well region of the second conductive type (first conductive type) of the dynamic threshold transistor of the first conductive type (second conductive type), and low impurity concentration layer of the second conductive type (first conductive type) has a thickness of not greater than 40 nm. Therefore, the expansion of the depletion layer formed on the shallow well region side from the gate insulation film is restrained depending on the layer of the high impurity concentration. As a result, the substrate bias effect is increased, and therefore, the off-state current can be reduced by raising the threshold value of the dynamic threshold transistor. Therefore, the semiconductor device, which is constructed of the complementary type circuit of the dynamic threshold transistors, is allowed to have low power consumption with the operating speed kept at high speed.

Moreover, the semiconductor device manufacturing method of the eighth aspect of the invention is the method of manufacturing the semiconductor device of the seventh aspect of the invention, at least comprising, after a process for forming the element isolation region, the steps of:

forming high impurity concentration regions of the second conductive type and the first conductive type in an uppermost layer portion of an active region defined as a region in which the element isolation region does not exist on the semiconductor substrate;

carrying out a process for depositing a semiconductor film all over a surface under condition that a monocrystalline semiconductor film is epitaxially grown selectively on the active region, and a polycrystalline semiconductor film is grown on a region other than the active region; and

removing the polycrystalline semiconductor selectively with respect to the monocrystalline semiconductor film.

According to the semiconductor device manufacturing method of this eighth aspect of the invention, the region of high impurity concentration is preliminarily formed in the uppermost layer portion of the active region, and the monocrystalline semiconductor film is subsequently epitaxially grown. Therefore, due to the dynamic threshold transistor of the first conductive type (second conductive type), the low impurity concentration layer of the second conductive type (first conductive type) and the high impurity concentration layer of the second conductive type (first conductive type) can be formed so as to have a steep profile that is hardly provided by ion implantation in the depthwise direction from the front surface side. Moreover, the film grown on the active region is the monocrystalline semiconductor film that succeeds the azimuth of the substrate crystal. Therefore, no special thermal process for recrystallization is needed, and a steep profile can be maintained.

Moreover, the polycrystalline semiconductor film capable of selectively etching the monocrystalline semiconductor film is formed on the regions other than the active region or, for example, the element isolation region. Therefore, in order to provide isolation between elements and between the source and drain regions, it is only required to remove the polycrystalline semiconductor film by isotropic etching.

Therefore, the semiconductor device of the seventh aspect of the invention can be manufactured through the comparatively simple processes.

Moreover, the semiconductor device manufacturing method of the ninth aspect of the invention is the method of manufacturing the semiconductor device of the seventh aspect of the invention, at least comprising, after a process for forming at least the element isolation region, the steps of:

forming high impurity concentration regions of the second conductive type and the first conductive type in an uppermost layer portion of an active region defined as a region in which the element isolation region does not exist on the semiconductor substrate; and

epitaxially growing a monocrystalline semiconductor film selectively only in the active region.

According to the semiconductor device manufacturing method of this ninth aspect of the invention, the region of high impurity concentration is preliminarily formed in the uppermost layer portion of the active region, and the monocrystalline semiconductor film is subsequently epitaxially grown. Therefore, for the dynamic threshold transistor of the first conductive type (second conductive type), the low impurity concentration layer of the second conductive type (first conductive type) and the high impurity concentration layer of the second conductive type (first conductive type) can be formed so as to have a steep profile that is hardly provided by ion implantation in the depthwise direction from the front surface side. Moreover, the film grown on the active region is the monocrystalline semiconductor film that succeeds the azimuth of the substrate crystal. Therefore, no special thermal process for recrystallization is needed, and a steep profile can be maintained.

Moreover, the monocrystalline semiconductor film is selectively epitaxially grown only in the active region. Accordingly, there is no need for isotropic etching or the like to provide isolation in the regions other than the active region, or, for example, between the elements and between the source and drain regions.

Therefore, the semiconductor device of the seventh aspect of the invention can be manufactured through simpler processes.

Moreover, the semiconductor device of the tenth aspect of the invention comprises:

a semiconductor substrate;

an element isolation region;

deep well regions of a first conductive type and a second conductive type, the regions being formed in the semiconductor substrate;

shallow well regions of the second conductive type and the first conductive type, the regions being formed respectively in the deep well regions of the first conductive type and the second conductive type; and

a plurality of gate electrodes formed via a gate insulation film on the shallow well regions of the second conductive type and the first conductive type,

the plurality of gate electrodes being electrically connected to the shallow well region of the second conductive type or the first conductive type, constituting dynamic threshold transistors of the first conductive type and the second conductive type, respectively,

the shallow well regions of the second conductive type and the first conductive type being electrically isolated by the element isolation region every one of the dynamic threshold transistors,

the second conductive type shallow well region having thereon a low impurity concentration layer of the first conductive type and a high impurity concentration layer of the first conductive type, which are formed successively in a depthwise direction from an interface side with the gate insulation film,

the first conductive type shallow well region having thereon a low impurity concentration layer of the second conductive type and a high impurity concentration layer of the second conductive type, which are formed successively in the depthwise direction from the interface side with the gate insulation film, and

the dynamic threshold transistors of the first conductive type and the second conductive type constituting a complementary type circuit.

According to the semiconductor device of this tenth aspect of the invention, the complementary type circuit is constructed of the dynamic threshold transistors of the first conductive type and the second conductive type. Then, the layer of low impurity concentration of the first conductive type (second conductive type) and the high impurity concentration layer of the first conductive type (second conductive type) are successively formed in the depthwise direction from the interface side of the gate insulating film in the shallow well region of the second conductive type (first conductive type) of the dynamic threshold transistor of the first conductive type (second conductive type). Also, with this so-called counter dope structure, the expansion of the depletion layer can be restrained similarly to the semiconductor device of the seventh aspect of the invention. Furthermore, the degree of restriction is greater than that of the semiconductor device of the seventh aspect of the invention. As a result, the substrate bias effect is further increased, and therefore, the off-state current can be reduced by further increasing the threshold value of the dynamic threshold transistor. Therefore, the semiconductor device, which is constructed of the complementary type circuit of the dynamic threshold transistors, is allowed to have further reduced power consumption with the operating speed kept at high speed.

Moreover, the semiconductor device of the eleventh aspect of the invention comprises:

a complementary type circuit comprised of a plurality of dynamic threshold transistors in which a well region segmented every element by an element isolation region is electrically connected with a gate electrode,

the plurality of dynamic threshold transistors having a substrate bias effect factor γ of not smaller than 0.3.

According to the semiconductor device of this eleventh aspect of the invention, a substrate bias effect sufficiently greater than that of the dynamic threshold transistor of the prior art can be obtained. Therefore, the semiconductor device, which is constructed of the complementary type circuit of the dynamic threshold transistors, is allowed to have low power consumption with the operating speed kept at high speed.

Moreover, the semiconductor device of the twelfth aspect of the invention is characterized by the semiconductor device of the sixth aspect of the invention and the semiconductor device of any one of the seventh, tenth or eleventh aspect of the inventions.

According to the semiconductor device of this twelfth aspect of the invention, the off-leak can be remarkably reduced by assembling the complementary type circuit with a dynamic threshold value of a large substrate bias effect, and the gate current can be remarkably reduced when the circuit is in the standby state. Therefore, the semiconductor device, which is constructed of the complementary type circuit of the dynamic threshold transistors, is allowed to have remarkably reduced power consumption with the operating speed kept at high speed.

Moreover, the static random access memory device of the thirteenth aspect of the invention is provided with the semiconductor device of any one of the sixth, seventh, tenth or eleventh aspect of the inventions.

According to the static random access memory device of this thirteenth aspect of the invention, there is provided the semiconductor device of any one of the sixth, seventh, tenth and eleventh aspect of the inventions, and therefore, the leak current in the standby stage can be reduced. Therefore, it is possible to achieve low power consumption with the operating speed of the static random access memory kept at high speed.

Moreover, the portable electronic equipment of the fourteenth aspect of the invention is provided the aforementioned semiconductor device or the static random access memory device.

According to the portable electronic equipment of this fourteenth aspect of the invention, there is provided the aforementioned semiconductor device. Therefore, the power consumption of the LSI (Large Scale Integrated Circuit) portion and so on is remarkably reduced, and the battery operating life can be largely extended.

### BRIEF DESCRIPTION OF THE DRAWINGS

FIG. 1 is a plan view of a memory cell of an SRAM device of a first embodiment of the present invention, showing a semiconductor active region, an element isolation region and a gate electrode (gate interconnection);

FIG. 2 is a plan view of the memory cell of the SRAM device of the first embodiment of the present invention, showing a gate electrode (gate interconnection) a gate electrode sidewall and contact holes;

FIG. 3 is a plan view of the memory cell of the SRAM device of the first embodiment of the present invention, showing a first layer metal interconnection and contact holes;

FIG. 4 is a plan view of the memory cell of the SRAM device of the first embodiment of the present invention, showing second layer and third layer metal interconnections and via holes;

FIG. 5 is a sectional view viewed from the cross-sectional line A-A′ of FIGS. 1 through 4;

FIG. 6 is a sectional view viewed from the cross-sectional line B-B′ of FIGS. 1 through 4;

FIGS. 7A through 7C are views showing procedures for fabricating the memory cell of the SRAM device of the first embodiment of the present invention;

FIGS. 8A through 8C are views showing procedures for fabricating the memory cell of the SRAM device of the first embodiment of the present invention;

FIG. 9 is a plan view of a memory cell of an SRAM device of a second embodiment of the present invention, showing a semiconductor active region, an element isolation region and a gate electrode (gate interconnection);

FIG. 10 is a sectional view of a memory cell of an SRAM device of a third embodiment of the present invention;

FIG. 11 is a graph showing a gate-voltage dependency of the drain current and the gate current of an n-channel type dynamic threshold transistor that constitutes a semiconductor device of a fourth embodiment of the present invention;

FIG. 12 is a graph showing a gate-voltage dependency of the drain current and the gate current of a p-channel type dynamic threshold transistor that constitutes the semiconductor device of the fourth embodiment of the present invention;

FIG. 13 is a diagram showing the construction of the semiconductor device of the fourth embodiment of the present invention;

FIG. 14 is a sectional view of a semiconductor device of a fifth embodiment of the present invention;

FIGS. 15A through 15C are views showing procedures for fabricating the semiconductor device of the fifth embodiment of the present invention;

FIGS. 16A and 16B are views showing procedures for fabricating the semiconductor device of the fifth embodiment of the present invention;

FIG. 17 is a sectional view of a semiconductor device of a sixth embodiment of the present invention;

FIG. 18 is a circuit diagram of a static random access memory device of an eighth embodiment of the present invention;

FIG. 19 is a view showing the construction of portable electronic equipment of a ninth embodiment of the present invention;

FIG. 20 is a plan view of a memory cell of a prior art SRAM device;

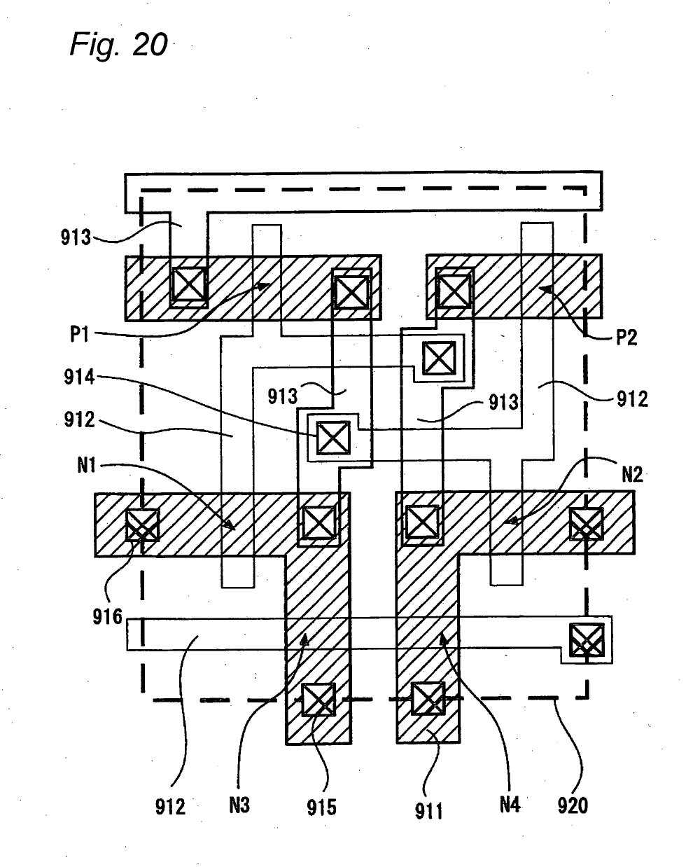

FIG. 21 is a plan view of the memory cell of the prior art SRAM device;

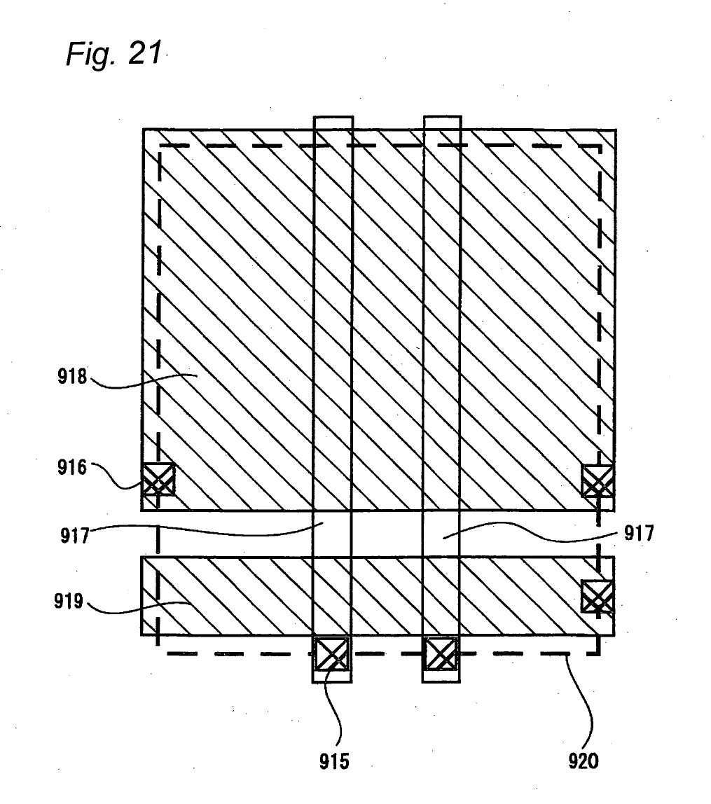

FIG. 22 is a graph showing a gate-voltage dependency of the drain current and the gate current of an n-channel type dynamic threshold transistor, for explaining the problem of the prior art; and

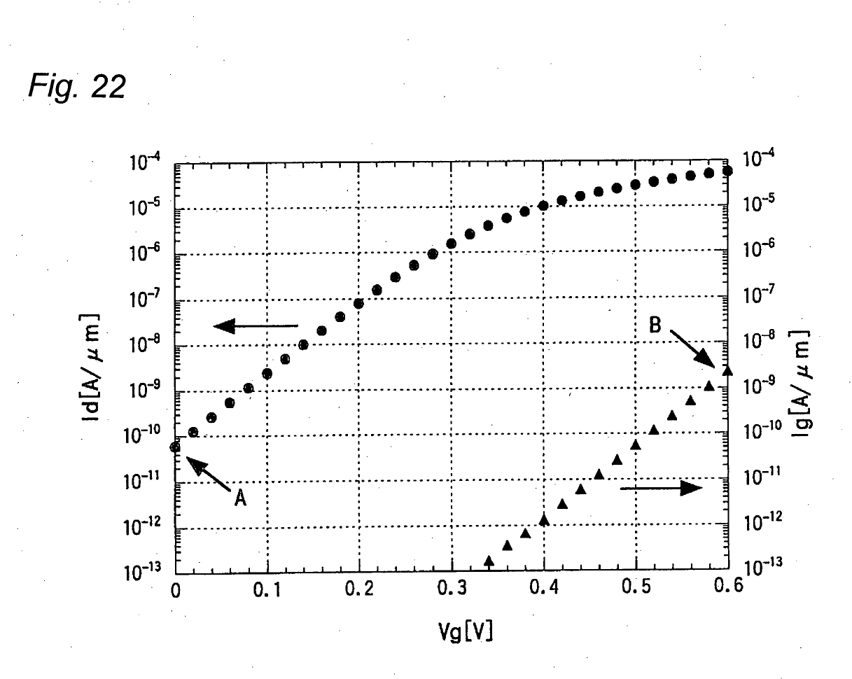

FIG. 23 is a circuit diagram of an inverter circuit constructed of dynamic threshold transistors, for explaining the problem of the prior art.

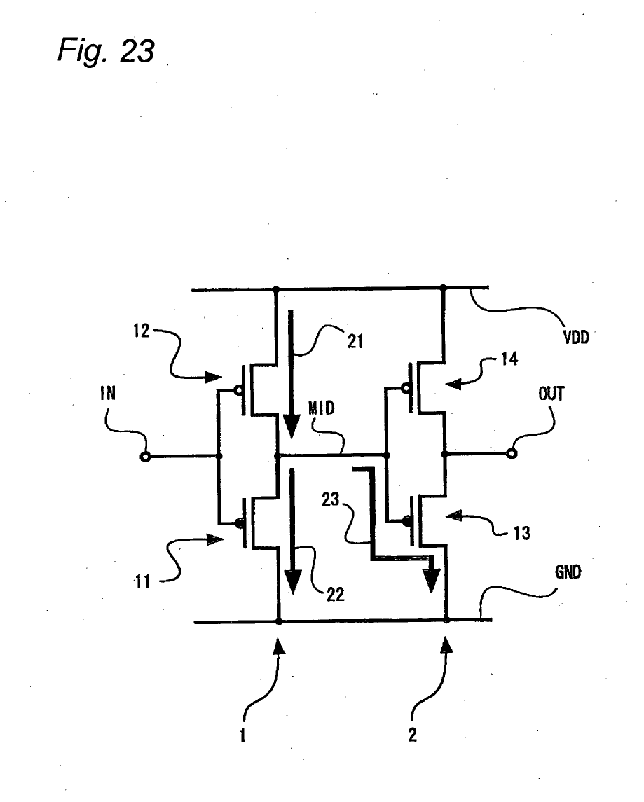

### BEST MODE FOR CARRYING OUT THE INVENTION

Although the semiconductor substrate that can be used for the present invention is not specifically limited, a silicon substrate is preferable. Moreover, the semiconductor substrate may have p-type or n-type conductive type. The following embodiments will be described on the basis of the p-type semiconductor substrate employed. Even when the n-type semiconductor substrate is employed, an SRAM device of similar functions can be formed through similar processes.

### FIRST EMBODIMENT

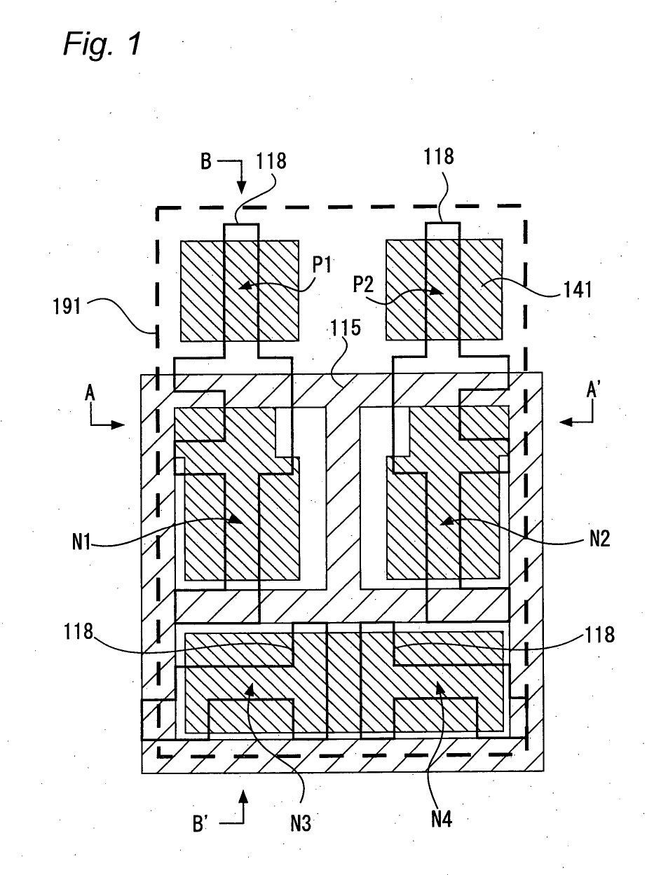

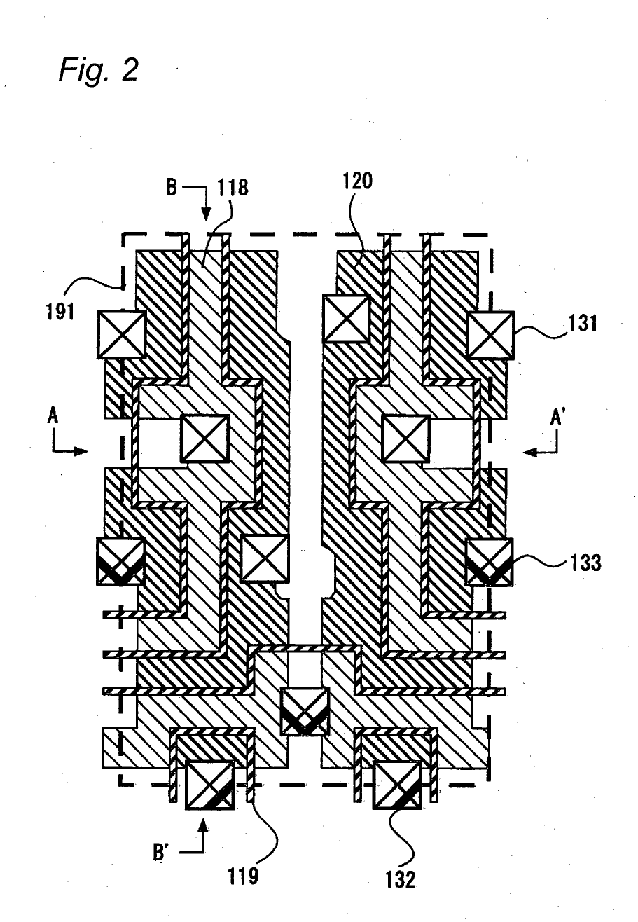

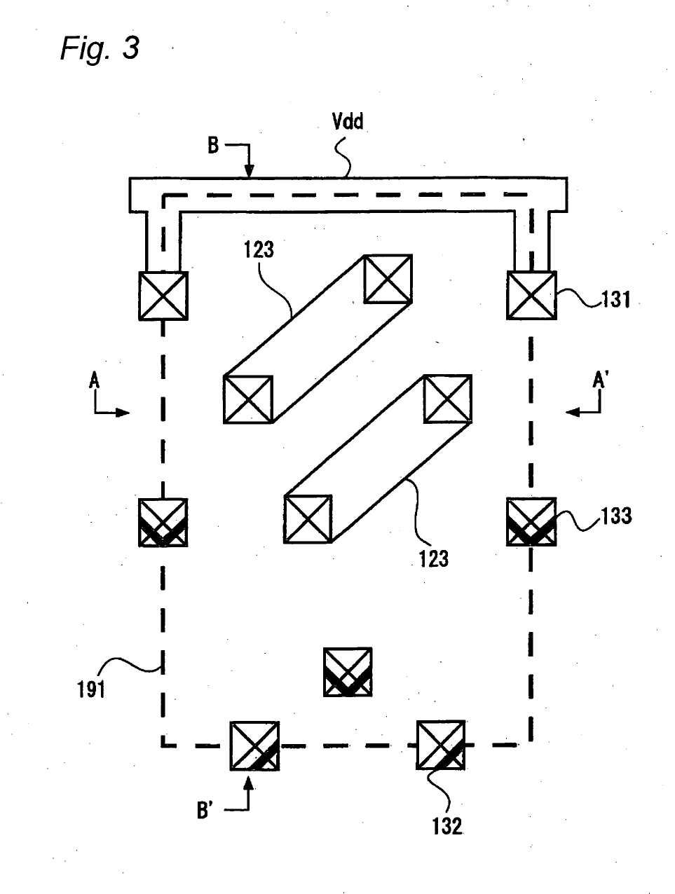

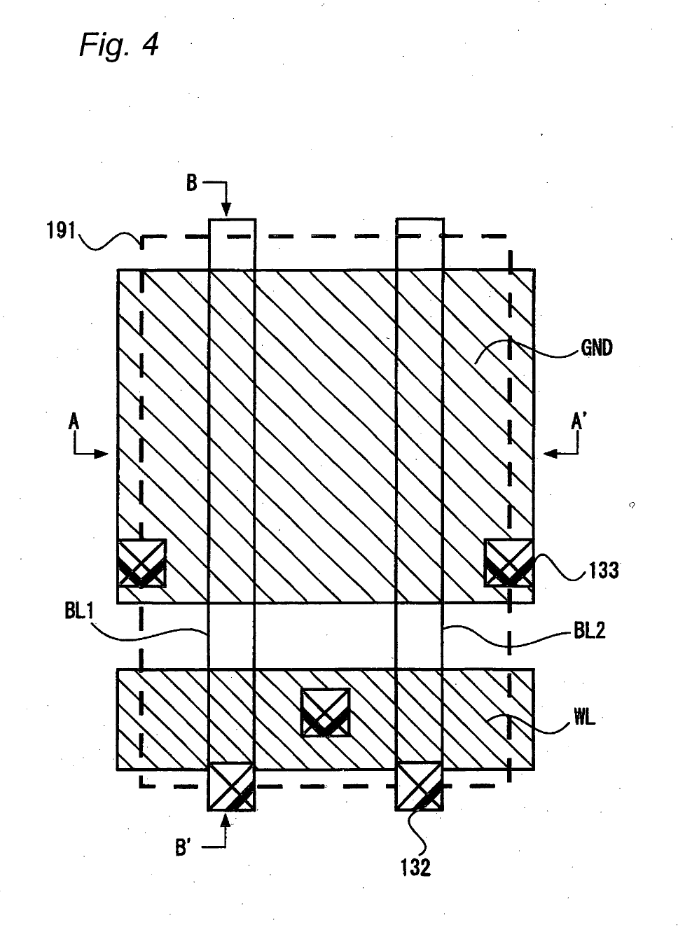

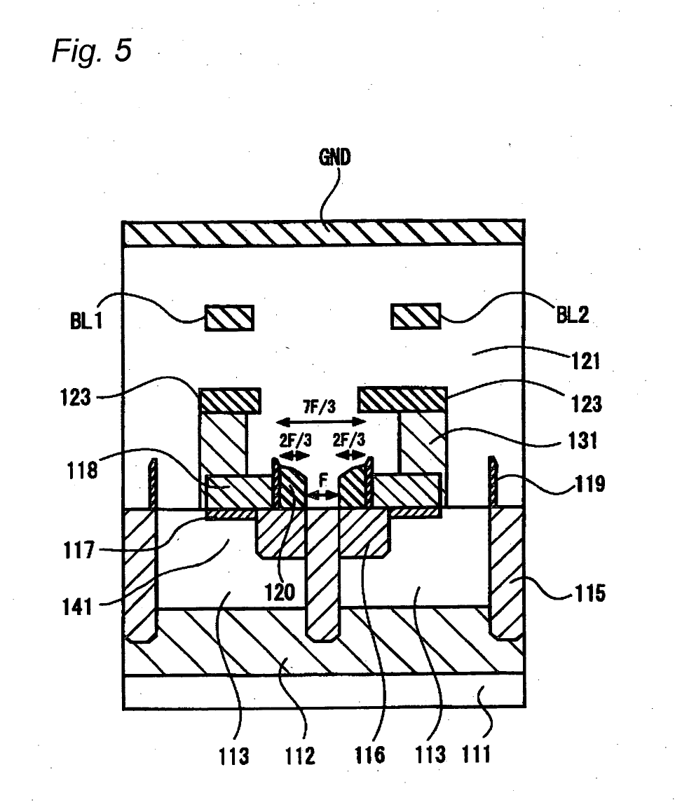

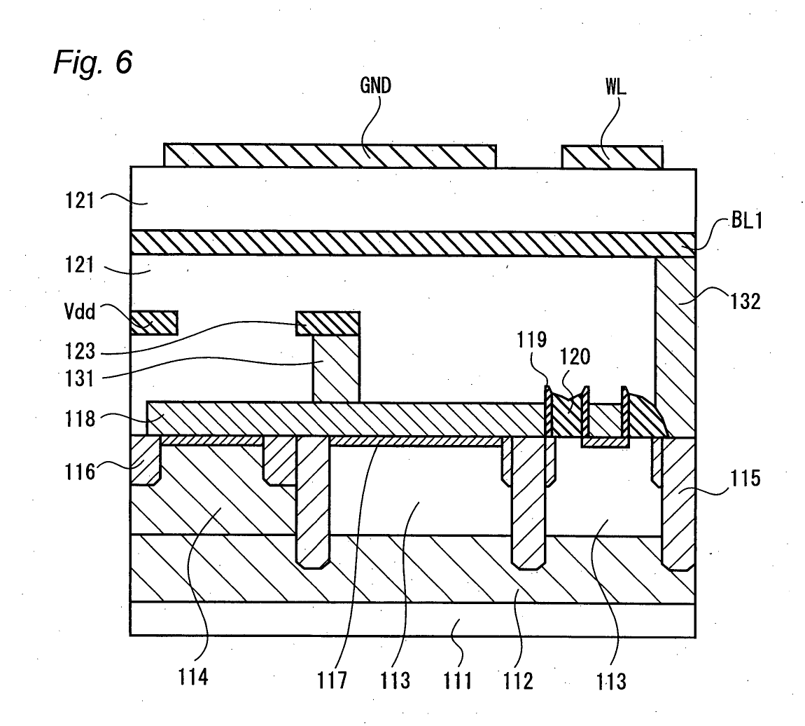

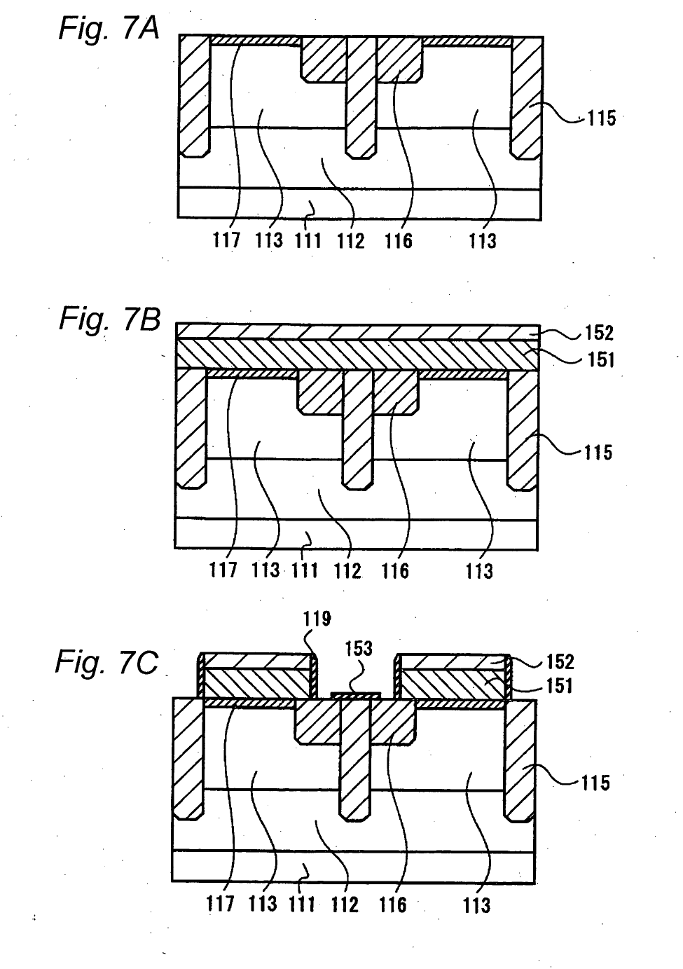

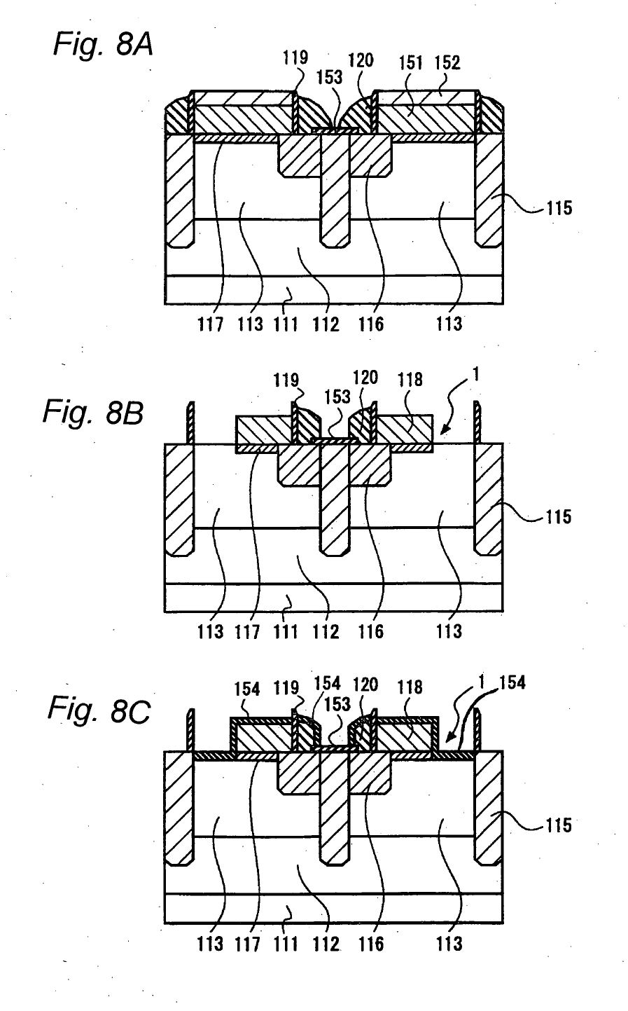

The first embodiment of the present invention will be described with reference to FIGS. 1 through 8. FIGS. 1 through 4 are plan views of the SRAM device of the present first embodiment. FIG. 1 shows semiconductor active regions, element isolation regions and gate electrodes (gate interconnections). FIG. 2 shows the gate electrodes (gate interconnections), gate electrode sidewalls and contact holes. FIG. 3 shows first layer metal interconnections and contact holes. FIG. 4 shows second layer and third layer metal interconnections and via holes. FIG. 5 is a sectional view viewed from the cross-sectional line A-A′ of FIGS. 1 through 4. FIG. 6 is a sectional view viewed from the cross-sectional line B-B′. FIGS. 7 and 8 are views showing procedures for fabricating the SRAM device of the present embodiment. In FIGS. 5, 6 and 8, the region of a high impurity concentration formed in the well region is not shown.

The construction of the semiconductor device of the present embodiment will be described first with reference to FIGS. 1 through 6. The SRAM device of the present embodiment is an SRAM constructed of six transistors. However, the number is not limited to this, and there may be an SRAM constructed of four transistors and two high resistance elements or an SRAM constructed of four transistors. The essence of the present invention resides not in the number, kind or combination of the elements that constitute the SRAM but in the arrangement that the diffusion layer is a stack type constituting part of interconnections.

As shown in FIGS. 5 and 6, an n-type deep well region 112 is formed in a p-type silicon substrate 111. A p-type shallow well region 113 and an n-type shallow well region 114 are formed on the n-type deep well region 112. As shown in FIGS. 1, 5 and 6, an active region 141 and element isolation regions are formed on the silicon substrate 111, and the element isolation regions are constructed of deep element isolation regions 115 and shallow element isolation regions 116. A gate electrode 118 constructed of a polysilicon film is formed on a gate insulation film 117 formed on the surface of the active region 141 and the element isolation regions. This gate electrode 118 plays the role of a gate interconnection. A gate electrode sidewall insulation film 119 constructed of a silicon nitride film is formed on a sidewall of the gate electrode 118, and a gate electrode sidewall conductive film 120 constructed of polysilicon is further formed on a sidewall of the gate electrode sidewall insulation film 119. Part of the gate electrode 118 and part of the gate electrode sidewall conductive film 120 are removed by etching. As shown in FIGS. 2, 3, 4, 5 and 6, a contact hole 131, an assembly of a contact hole and a first via hole (the assembly is indicated by 132) or an assembly of a contact hole and a first via hole and a second via hole (the assembly is indicated by 133) are formed on the gate electrode 118, the gate electrode sidewall conductive film 120 and the active region 141. The contact hole 131 is to connect first layer metal interconnections Vdd and 123 with a lower layer structure. The first via hole 132 is to connect second layer metal interconnections BL1 and BL2 with the first layer metal interconnections Vdd and 123. The second via hole 133 is to connect third layer metal interconnections GND and WL with the second layer metal interconnections BL1 and BL2. The metal interconnection layers and the lower layer structure are isolated from each other by an interlayer insulation film 121. The first layer metal interconnections Vdd and 123 are constructed of a power line Vdd and an interconnection 123. The second layer metal interconnections BL1 and BL2 are constructed of a first bit line BL1 and a second bit line BL2. The third layer metal interconnections GND and WL are constructed of a grounding line GND and a word line WL. In FIGS. 1 through 4, the reference numeral 191 denotes a boundary of a unit memory cell.

Six MOSFET's are formed in the unit memory cell. In FIG. 1, there are shown n-type MOSFET's N1 through N4 and p-type MOSFET's P1 and P2. The four transistors (MOSFET's) N1, N2, P1 and P2 constitute a flip-flop circuit, and the two transistors (MOSFET's) N3 and N4 constitute transfer gate transistors.

The transistors N1 through N4 are dynamic threshold transistors in which the gate electrode and the p-type shallow well region 113 are electrically connected with each other by a method described later. The dynamic threshold transistors, of which the threshold value can be lowered without increasing the off-leak current, are therefore able to be driven on a low voltage and operate at high speed. By employing the dynamic threshold transistors N1 through N4 for an SRAM, the low-voltage driving and high-speed operation of the SRAM are achieved. The driving ability of the p-type MOSFET's (P1, P2) is not important in improving the operating speed when an operation method of precharging the bit line with the power voltage is adopted, and therefore, it is preferable to provide only the n-type MOSFET's by dynamic threshold transistors. With this arrangement, a margin for connecting the gate electrode 118 with the shallow well region 113 can be reduced.

In the present first embodiment, it is acceptable to replace the n-type MOSFET's with the p-type MOSFET's (providing a construction of four p-type MOSFET's and two n-type MOSFET's). However, as in the present first embodiment, it is most preferable to provide the four n-type MOSFET's (N1 through N4) by dynamic threshold transistors. The reason for the above is that the driving ability of the n-channel type MOSFET is generally higher than that of the p-channel type MOSFET, and accordingly, a faster SRAM device is provided. Otherwise, a high driving power can be obtained even if the gate width of the n-channel type MOSFET's (N1 through N4) is reduced, and therefore, the memory cell area can be shrunk.

Since the gate electrode 118 and the shallow well region 113 are electrically connected with each other in the dynamic threshold transistors (MOSFET's) N1 through N4, the potential of the shallow well region 113 fluctuates. Therefore, the shallow well region 113 of the dynamic threshold transistors N1 through N4 must be isolated every element. Therefore, the depth of the deep element isolation region 115 is formed with a depth sufficient for electrically isolating the p-type shallow well region 113. This arrangement enables the prevention of interference between elements.

Moreover, the element isolation region, which may have a single depth, should more preferably be constructed of two types of the deep element isolation region 115 and the shallow element isolation region 116. It is difficult to form deep element isolation regions 115 of various widths due to the characteristics of the embedment process of the insulation film. On the other hand, although it is easy to form shallow element isolation regions 116 of various widths, it is difficult to isolate the shallow well region 113 every element. Therefore, by combining the shallow element isolation region 116 with the deep element isolation region 115, it becomes possible to isolate the shallow well region 113 with a small margin every element and form element isolation regions of various widths.

Procedures for forming the SRAM device of the present first embodiment will be described with reference to FIGS. 7 and 8. FIGS. 7A through 7C and FIGS. 8A through 8C show the steps of forming the SRAM device by sectional views viewed from the cross-sectional line A-A′ of FIGS. 1 through 4.

First of all, the element isolation regions 115 and 116 are formed in the p-type silicon substrate 111. These element isolation regions 115 and 116 are constructed of the deep element isolation region 115 and the shallow element isolation region 116. Next, there is carried out impurity ion implantation for forming the n-type deep well region 112, the n-type shallow well region 114 (see FIG. 6) and the p-type shallow well region 113 in the p-type silicon substrate 111. The depth of the junction between the n-type deep well region 112 and the p-type shallow well region 113 is determined by the impurity ion implantation condition and the subsequently effected thermal history, and the conditions of the processes are determined so that the p-type shallow well region 113 is electrically isolated by the deep element isolation region 115. Next, as shown in FIG. 7A, a gate oxide film 117 is formed as one example of the gate insulation film. The material of the gate insulation film is not limited to the aforementioned example, and the material is not specifically limited so long as it has an insulative property. When the silicon substrate 111 is employed, there can be employed a silicon oxide film, a silicon nitride film or a laminate of them. Moreover, a high dielectric film such as an aluminum oxide film, a titanium oxide film, a tantalum oxide film or a laminate of them can also be employed. The gate insulation film 117 should preferably have a thickness of 1 to 10 nm when the silicon oxide film is employed. The gate insulation film 117 can be formed by the methods of the CVD (Chemical Vapor Deposition) method, the sputtering method, the thermal oxidation method and so on.

Next, as shown in FIG. 7B, a polysilicon film 151 as a first conductive film that becomes the gate electrode and a first insulation film 152 are formed. It is acceptable to replace the polysilicon film 151 with another conductive film so long as it has a conductive property. When the silicon substrate 111 is employed as a semiconductor substrate, there are enumerated monocrystalline silicon, aluminum, copper and so on besides polysilicon. The conductive film should preferably have a thickness of 0.1 to 0.4 μm. The conductive film can be formed by the methods of the CVD method, the deposition method and so on. The first insulation film 152 should preferably be a silicon oxide film and have a thickness of 0.05 to 0.25 μm. The first insulation film 152 can be formed by the methods of the CVD method, the sputtering method, the thermal oxidation method and so on.

Next, patterning of the polysilicon film 151 and the first insulation film 152 is carried out. In order to carry out this patterning, it is proper to use a patterned photoresist as a mask and etch the first insulation film 152 and the polysilicon film 151. Moreover, it is also acceptable to etch only the first insulation film 152 using a photoresist as a mask and etch the polysilicon film 151 using the first insulation film 152 as a mask after removing the photoresist.

Next, as shown in FIG. 7C, the gate electrode sidewall insulation film 119 and the second insulation film 153 are formed. This gate electrode sidewall insulation film 119 tightly fits to the sidewall of the pattern of the polysilicon film 151. The gate electrode sidewall insulation film 119 and the second insulation film 153 should preferably be constructed of a silicon nitride film. The gate electrode sidewall insulation film 119 and the second insulation film 153 can be concurrently formed by depositing a silicon nitride film and thereafter carrying out etchback by masking part of them with a photoresist. The silicon nitride film should preferably have a thickness of, for example, 0.02 μm to 0.1 μm. The function of the second insulation film 153 is to protect the silicon substrate and the element isolation region from various etching processes and important particularly in the etching process for removing the first insulation film 152. It is to be noted that the second insulation film 153 is not shown in the figures except for FIGS. 7A-7C and 8A-8C.

Next, as shown in FIG. 8A, a gate electrode sidewall conductive film 120 is formed as a second conductive film. In order to form this gate electrode sidewall conductive film 120, it is proper to deposit polysilicon all over the surface and thereafter carry out etchback. At this time, although a semiconductor such as amorphous silicon and a conductive material can be employed besides polysilicon, the polysilicon is most preferable. The reason for the above is that it is easy to shallow the junctions between the source region and the drain region and the well region since the impurity diffusion speed of polysilicon is extremely greater than in the well region, and the control of the short-channel effect can easily be achieved.

Next, the first insulation film 152 is removed by etching. This etching can be carried out by isotropic etching. If the element isolation region is exposed on the surface during this etching, then the element isolation region is disadvantageously etched when the element isolation region is made of the same material as that of the first insulation film. Therefore, the element isolation region should preferably be completely covered with the second insulation film 153 or the gate electrode sidewall conductive film 120 prior to this etching.

Next, as shown in FIG. 8B, the polysilicon film 151 and the gate electrode sidewall conductive film 120 are partially removed by anisotropic etching that has selectivity to the gate electrode sidewall insulation film 119 using a photoresist as a mask. The gate electrode sidewall conductive film 120 is isolated into a plurality of regions by this anisotropic etching, and the regions constitute a source region, a drain region or a stack type diffusion layer interconnection after impurity implantation and impurity diffusion, respectively. Moreover, the polysilicon film 151 becomes a gate electrode or a gate interconnection. If the polysilicon film 151 on the active region is etched (the region connecting the gate electrode with the shallow well region indicated by 1 in FIG. 8B) during the anisotropic etching, then the gate electrode and the p-type shallow well region 113 can be electrically connected with each other in the silicide process described later.

Next, impurity ion implantation into the gate electrode and the gate electrode sidewall conductive film is carried out, and annealing for impurity activation is carried out. Although not shown, an impurity for giving the conductive type identical to that of the shallow well region is implanted also into the region 1 that connects the gate electrode with the shallow well by the above-mentioned impurity ion implantation. A source region and a drain region are formed by the annealing for the impurity implantation and the impurity activation. Although not shown, the impurity seeps from the gate electrode sidewall conductive film 120 toward the shallow well region by the annealing for the impurity activation. Consequently, a high impurity concentration region of the conductive type opposite to that of the shallow well region is formed in the shallow well region. Then, the gate electrode sidewall conductive film 120 and the high impurity concentration region of the conductive type opposite to the shallow well region integrally form the source region or the drain region.

The ion implantation of the source region and the drain region can be carried out on the condition of an implantation energy of 10 to 180 KeV and a dosage of 1×10¹⁵ to 2×10¹⁶ cm⁻² when, for example, ⁷⁵As⁺ is employed as an impurity ion, on the condition of an implantation energy of 5 to 100 KeV and a dosage of 1×10¹⁵ to 2×10¹⁶ cm⁻² when ³¹P⁺ is employed as an impurity ion or on the condition of an implantation energy of 5 to 40 KeV and a dosage of 1×10¹⁵ to 2×10¹⁶ cm⁻² when ¹¹B⁺ ion is employed as an impurity ion.

Next, as shown in FIG. 8C, a silicide film 154 is formed on the gate electrode 118 and the gate electrode sidewall conductive film 120. At this time, in the region 1 that connects the gate electrode 118 with the shallow well, the gate electrode 118 and the p-type shallow well region 113 are electrically connected with each other by the silicide film 154. As a result, the MOSFET's (N1 through N4), which have this gate electrode 118, become dynamic threshold transistors.

Subsequently, upper interconnections are formed by means of a well-known technique to complete the SRAM device.

When the SRAM device is formed according to the aforementioned procedures, the gate electrode sidewall conductive film 120 is formed on the sidewall of the gate electrode 118 via the gate electrode sidewall insulation film 119. By properly removing this gate electrode sidewall conductive film 120 by etching that has selectivity to the gate electrode sidewall insulation film 119, the isolation between the source region and the drain region and the formation of the local interconnections by the gate electrode sidewall conductive films 120 are concurrently achieved. Further, the gate electrode 118 is properly removed by the etching that has selectivity to the gate electrode sidewall insulation film 119, and therefore, the gate electrode interconnection is concurrently formed. Further, if the gate electrode 118 on the active region is removed by the etching that has selectivity to the gate electrode sidewall insulation film 119 when providing a dynamic threshold transistor, then the region for electrically connecting the gate electrode 118 with the shallow well region can be concurrently formed. Therefore, various purposes are achieved through the only one-time etching process, and therefore, the manufacturing cost can be reduced by simplifying the manufacturing processes of the static random access memory device.

In the SRAM cell of the present first embodiment, the number of contact holes per unit cell is eight, which is reduced by two in comparison with that of the prior art SRAM cell that has a similar device construction. The reason why the contact holes are reduced by two is that the drain electrode of the MOSFET (N1) is connected to the drain electrode of the MOSFET (P1), and the drain electrode of the MOSFET (N2) is connected to the drain electrode of the MOSFET (P2) each by the stack type diffusion layer interconnections constructed of polysilicon.

Moreover, the stack type diffusion layer interconnections can be formed with a pitch smaller than that of metal interconnections. For example, when two interconnections are formed parallel to each other, the following results. Assuming that the minimum processing dimension is F, then a width of 3 F is needed since the line widths of the two metal interconnections are each F and the metal interconnection interval is F. On the other hand, when the stack type diffusion layer is employed as shown in FIG. 5, there is needed a dimension of only (7/3)F. In this case, the alignment deviation of the etching process with respect to the stack type diffusion layer interconnections is (⅓)F, the interconnection width is required to be (⅓)F at a minimum, and the etching width is F. That is, by using the stack type diffusion layer, the margin can be reduced than when metal interconnections are adopted.

For the above reasons, the number of contact holes is reduced in comparison with the memory cell of the prior art SRAM, and the interconnections are simplified by employing the stack type diffusion layer interconnection in the memory cell of the SRAM of the present first embodiment. Therefore, the memory cell area can be shrunk.

In the SRAM device of the present first embodiment, since the stack type diffusion layer is employed as part of the interconnections, the number of contact holes can be reduced and the interconnections are simplified. Accordingly, there is provided an SRAM device of high integration with shrunk cell area.

Furthermore, the n-type MOSFET's (N1 through N4) are provided by the dynamic threshold transistors that have high driving ability at a low voltage, and therefore, a high-speed SRAM device of low voltage drive and low power consumption is provided.

### SECOND EMBODIMENT

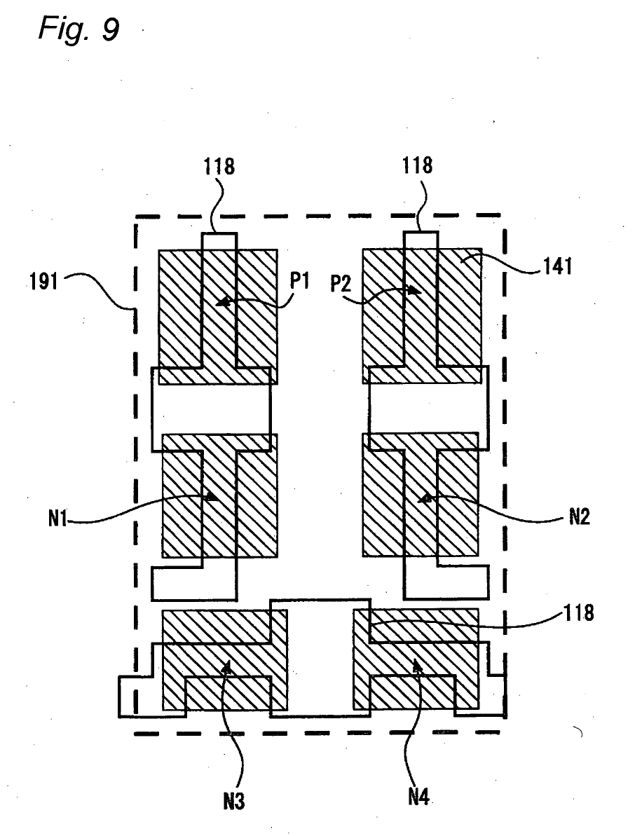

The second embodiment of the present invention will be described with reference to FIG. 9. It is to be noted that the components similar to those of the first embodiment are denoted by same reference numerals and no description is provided therefor. FIG. 9 is a plan view of the SRAM device of the present second embodiment, showing only the semiconductor active region and the gate electrode (gate interconnection). The construction of the SRAM device of the present second embodiment differs from the construction of the SRAM device of the first embodiment only in that no dynamic threshold transistor is employed. Therefore, the concrete structure differs in the following points. Firstly, the well region is not required to have a two-layer structure in which the well region is constructed of a shallow well region and a deep well region but allowed to have a structure similar to that of the prior art SRAM device. Secondly, the shallow well region is not required to be electrically isolated. Therefore, no deep well region is needed, and for example, STI (Shallow Trench Isolation) can be used. Thirdly, there is no need to provide a region for connecting the gate electrode with the well region. Therefore, the cell area is shrunk in comparison with the case of the first embodiment.

Also, in the SRAM device of the present second embodiment, the stack type diffusion layer is employed as part of interconnections. Therefore, the number of contact holes can be reduced, and the interconnections are simplified. Accordingly, there is provided an SRAM device of a small memory cell area and high integration.

### THIRD EMBODIMENT

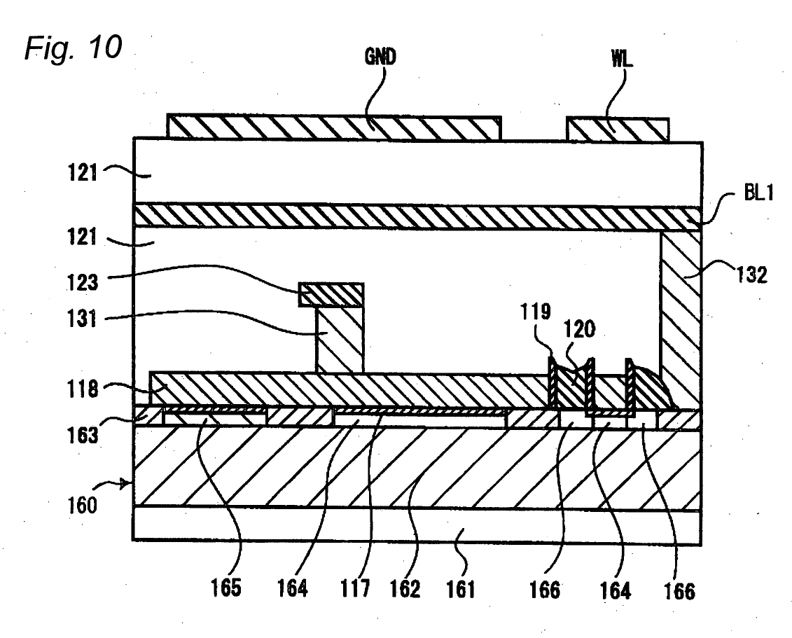

The third embodiment of the present invention will be described with reference to FIG. 10. FIG. 10 is a sectional view of the SRAM device of the present third embodiment. The SRAM device of the present third embodiment differs from the SRAM devices of the first or second embodiment in that a SOI substrate 160 is employed as a semiconductor substrate. Therefore, the components similar to those of the first and second embodiments are denoted by same reference numerals and no detailed description is provided therefor.

In FIG. 10, there are shown a silicon substrate 161, an embedded oxide film 162, an element isolation region 163, a p-type body region 164, an n-type body region 165 and an n-type high impurity concentration region 166 (constituting part of the source region and the drain region). The superstructure other than the substrate is the same as that of the first or second embodiment. The elements constituting the SRAM device may include or exclude a dynamic threshold transistor. In order to form a dynamic threshold transistor, it is proper to electrically connect the gate electrode 118 with the body region 164. FIG. 10 corresponds to a sectional view viewed from the cross-sectional line B-B′ in FIG. 1.

The SOI substrate 160 is employed as the semiconductor substrate in the SRAM device of the present third embodiment. Therefore, the junction area of the source region and the drain region is reduced, and the electrostatic capacity can be remarkably reduced. Particularly, when a dynamic threshold transistor is included, the effective electrostatic capacity is increased since the potential of the body region 164 changes according to the change in the potential of the gate electrode 118. Therefore, the reduction in the junction area of the source region and the drain region due to the SOI substrate 160 and the effect of the reduction in the electrostatic capacity due to the existence of the thick embedded oxide film become remarkable.

Furthermore, the isolation between elements can be effectively achieved merely by isolating the thin SOI layer in forming the element isolation region, and therefore, the element isolation process is facilitated. Particularly, in the case where a dynamic threshold transistor is included, the element isolation region has been required to be deepened to electrically isolate the shallow well region when a bulk substrate is employed. However, if the SOI substrate is employed, the element isolation region is allowed to be the same as in the case where no dynamic threshold transistor is included. Therefore, in the case where a dynamic threshold transistor is included, the effect of simplifying the element isolation region formation process by the use of the SOI substrate becomes remarkable.

### FOURTH EMBODIMENT

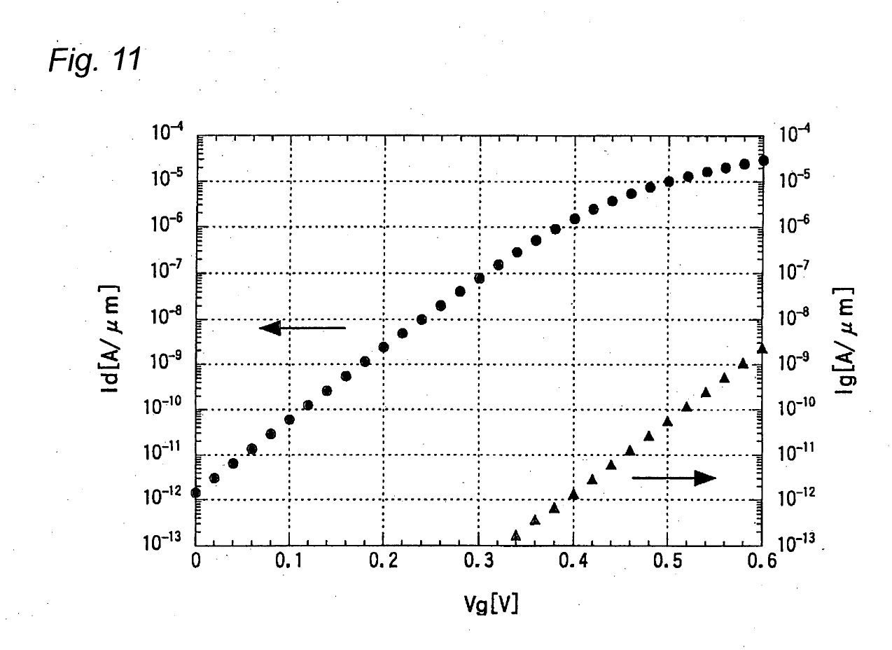

The present embodiment is related to a semiconductor device in which a leak current attributed to a gate current in the standby stage is reduced while keeping the operating speed of the circuit by changing the power voltage depending on when the circuit is in the active state or in the standby state in a CMOS circuit constructed of dynamic threshold transistors. In this case, the active state means that the circuit is in an active mode in which the circuit is operated at high speed, and the standby state means that the circuit is in a standby mode in which the circuit is operated at low speed or put into a stop state. The semiconductor device of the present fourth embodiment will be described with reference to FIGS. 11 through 13.

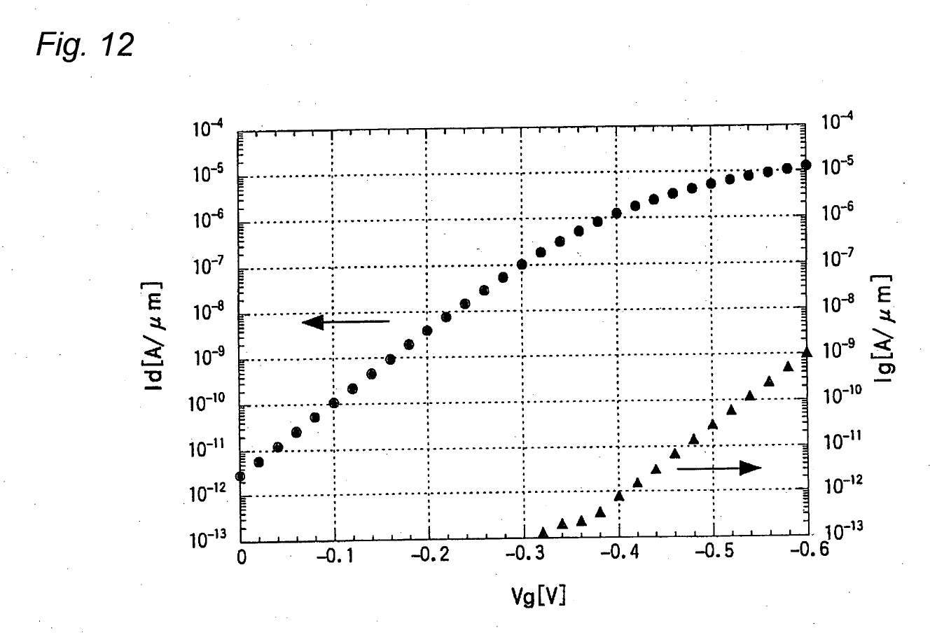

FIG. 11 is a graph showing the characteristic of the drain current (Id) and the gate current (Ig) with respect to the gate voltage (Vg) of one example of the n-channel type dynamic threshold transistor. FIG. 12 is a similar graph of one example of the p-channel type dynamic threshold transistor. It is to be noted that Id and Ig are normalized to a current value per unit gate width.

From the viewpoint of the operating speed of the circuit, the operating speed can be made faster as the drain current is increased, and therefore, it is better to raise the power voltage within a range in which the gate current does not significantly increase. In the example of FIG. 11, the power voltage can be set to, for example, 0.6 V. However, when the circuit is substantially in the stop state (standby state), the gate current occupies the greater part of power consumption. As a method for reducing the consumption current due to the gate current, there is a method for interrupting the power supplied to the circuit. By this operation, the consumption current of the circuit can be made zero. However, if the power supplied to the circuit is interrupted, then the state (information) at each node of the circuit is disadvantageously lost. In order to prevent this, it is proper to provide a nonvolatile memory and store the state in this memory before the power is cut off.

Another method for reducing the consumption current due to the gate current without providing the nonvolatile memory for storing the aforementioned state is to lower the power voltage when the circuit is in the standby state. The gate current is exponentially reduced if the power voltage is lowered, and therefore, the consumption current of the circuit in the standby state can be remarkably reduced. In addition, the state at each node of the circuit is maintained, and accordingly, there is no need to separately provide a nonvolatile memory. Moreover, there is no need of the operation of writing the state of the circuit into the nonvolatile memory or conversely reading the state from the nonvolatile memory.

With regard to the power voltage in the standby stage, it is more preferable to set the gate current equal to or smaller than the off-leak current. In the example of FIG. 11, the off-leak current is about 10⁻¹² A/μm, and the gate current becomes equal to it when the gate voltage is 0.4 V. Moreover, in FIG. 12, the p-channel type dynamic threshold transistor has almost same characteristics except for the different point that the gate voltage is inverted in polarity. Therefore, in the example of FIG. 11, it is more preferable to set the power voltage equal to or lower than 0.4 V when the circuit is in the standby state. Of course, the off-leak current largely changes depending on the threshold value of the element, and therefore, it is proper to determine the power voltage in the standby stage so that the gate current becomes equal to or smaller than the off-leak current.

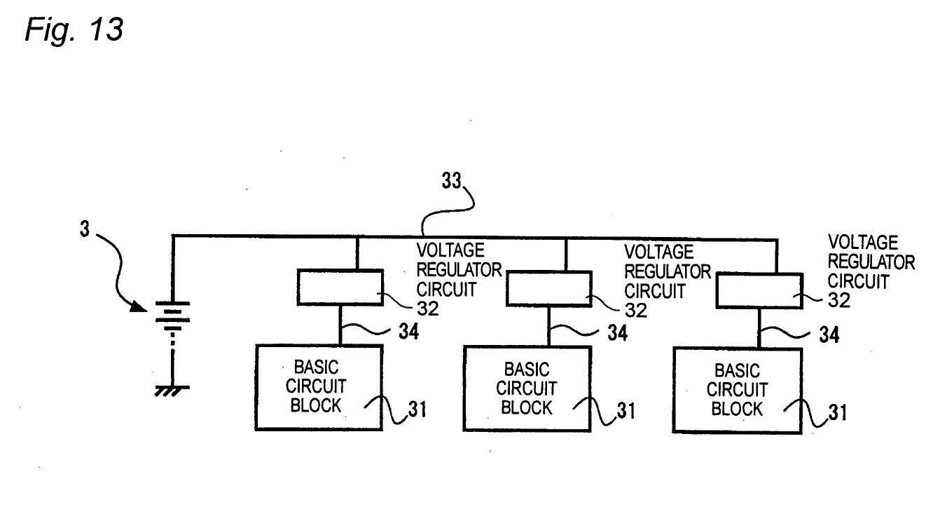

FIG. 13 is a diagram showing the construction of the semiconductor device of the present embodiment. A basic circuit block 31 constructed of a CMOS circuit of dynamic threshold transistors is supplied with a power from a power supply 3 via a power line 33, a voltage regulator circuit 32 and a power line 34. The voltage regulator circuit 32 supplies a varied voltage to the power line 34 depending on when the corresponding basic circuit block 31 is in the active state or in the standby state. If the dynamic threshold transistors that constitute the basic circuit block 31 have characteristics as shown in FIGS. 11 and 12, then a voltage of, for example, 0.6 V is supplied when the basic circuit block 31 is in the active state and a voltage of 0.4 V is supplied when the basic circuit block 31 is in the standby state.

There may be provided a plurality of basic circuit blocks 31 as shown in FIG. 13. In this case, the leak current can be restrained by lowering only the power voltage supplied to the basic circuit block that should be put into the standby state. Therefore, when only part of the circuits is operated, low power consumption can be achieved with the operating speed of the circuit kept at high speed by appropriately separating the circuit that should be put into the standby state from the circuits that should be put into the active state.

It is to be noted that the transistors that constitute the basic circuit block 31 are not required to be constructed of only dynamic threshold transistors but allowed to be partially constructed of normal MOSFET's.

According to the semiconductor device of the present embodiment, it is possible to change the power voltage depending on when the basic circuit block constructed of the CMOS circuit of dynamic threshold transistors is in the active state or in the standby state and lower the power voltage in the standby state. Therefore, when the circuit is in the standby state, the gate current, which occupies the greater part of the leak current of the CMOS circuit constructed of dynamic threshold transistors, can be largely reduced. On the other hand, a sufficiently large drain current can be obtained when the circuit is in the active state, and therefore, the circuit can be operated at high speed. Therefore, the semiconductor device constructed of the CMOS circuit of dynamic threshold transistors is allowed to have reduced power consumption with the operating speed kept at high speed.

### FIFTH EMBODIMENT

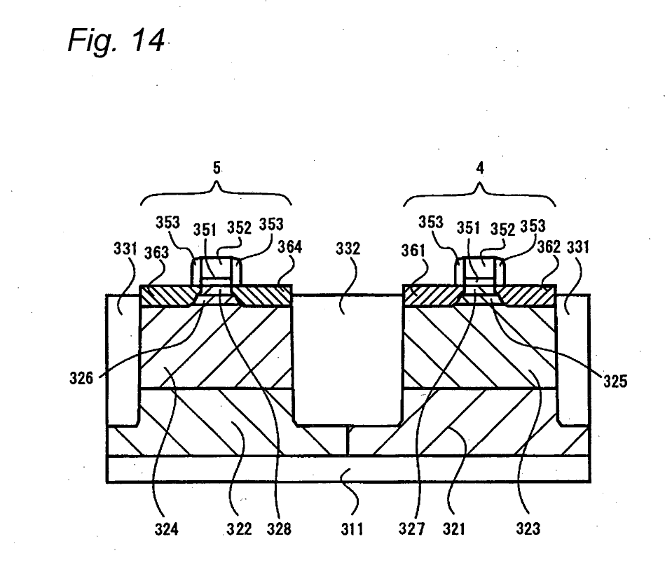

The semiconductor device of the present fifth embodiment is to raise the threshold value for obtaining the desired drain current and consequently reduce the off-state current by increasing the substrate bias effect of the dynamic threshold transistors in the CMOS circuit constructed of dynamic threshold transistors. The semiconductor device of the present fifth embodiment will be described with reference to FIGS. 14 through 16.

FIG. 14 is a schematic view of the cross-section of the semiconductor device of the present fifth embodiment, where an n-channel type dynamic threshold transistor 4 and a p-channel type dynamic threshold transistor 5 are illustrated. An n-type deep well region 321 and a p-type deep well region 322 are formed on a semiconductor substrate 311. Further, a p-type shallow well region 323 is formed on the n-type deep well region 321, while an n-type shallow well region 324 is formed on the p-type deep well region 322.

An n-type source region 361 and an n-type drain region 362 are formed apart from each other on the p-type shallow well region 323, and a gate electrode 352 is formed via a gate insulation film 351 on a region between them. Further, a gate sidewall insulation film 353 is formed on the sidewall of the gate electrode 352. Although not shown, the gate electrode 352 and the p-type shallow well region 323 are electrically connected with each other, constituting the n-channel type dynamic threshold transistor 4. On the other hand, a p-type source region 363 and a p-type drain region 364 are formed apart from each other on the n-type shallow well region 324, and a gate electrode 352 is formed on a region between them via the gate insulation film 351. Further, the gate sidewall insulation film 353 is formed on the sidewall of the gate electrode 352. Although not shown, the gate electrode 352 and the n-type shallow well region 324 are electrically connected with each other, constituting the p-channel type dynamic threshold transistor 5.

In order to provide isolation between elements, the element isolation regions 331 and 332 are provided. The element isolation regions 331 and 332 have a depth sufficient for electrically isolating the shallow well regions 323 and 324 of the dynamic threshold transistors from each other. With this arrangement, interference between the elements can be prevented even if the potentials of the shallow well regions 323 and 324 electrically connected to the gate electrode 352 fluctuate every element.

A p-type low impurity concentration region 327 is formed just under the gate insulation film 351 of the n-channel type dynamic threshold transistor 4, and a p-type high impurity concentration region 325 is further formed under the region. On the other hand, an n-type low impurity concentration region 328 is formed just under the gate insulation film 351 of the p-channel type dynamic threshold transistor 5, and an n-type high impurity concentration region 326 is further formed under the region. The p-type low impurity concentration region 327 and the n-type low impurity concentration region 328 are allowed to have a thickness of, for example, 5 nm to 40 nm and have an impurity concentration of, for example, 1×10¹⁷ cm⁻³ to 5×10¹⁸ cm⁻³. It is proper to determine the impurity concentrations of the low impurity concentration regions 327 and 328 so that the dynamic threshold transistors come to have the desired threshold values. The high impurity concentration region 325 and the n-type high impurity concentration region 326 are allowed to have a thickness of, for example, 5 nm to 50 nm and have an impurity concentration of, for example, 2×10¹⁹ cm⁻³ to 5×10²⁰ cm⁻³. Lower ends of the high impurity concentration regions 325 and 326 should preferably be shallower than the lower surfaces of the source and drain regions 361 through 364. The reason for the above is that a large capacitance is added to the junctions between the high impurity concentration regions 325 and 326 and the source and drain regions 361 through 364 as a consequence of significantly narrowed width of the depletion layer and it is preferable to reduce their junction areas as far as possible.

The substrate bias effect of the dynamic threshold transistor is considered. Although the n-channel type dynamic threshold transistor is considered here, the same thing can be said for the p-channel type dynamic threshold transistor except for the inversion in polarity. The substrate bias effect is the effect that the threshold value of the transistor is lowered and the drain current is increased when a bias is applied to the shallow well region. It is convenient to use a substrate bias effect factor γ as an amount that represents the magnitude of the substrate bias effect.

γ=|ΔVt/Vb| (1)

In the above expression, Vb represents the voltage applied to the shallow well region with respect to the potential of the source region served as a reference, and ΔVt represents the shift amount (negative value) of the threshold value as a consequence of the application of the voltage Vb to the shallow well region. It is to be noted here that the threshold value is the threshold value in a state in which the voltage Vb is consistently applied to the shallow well region and is different from the threshold value actually measured at the dynamic threshold transistor in which the voltage of the shallow well region fluctuates. It is assumed that γ is obtained from ΔVt when Vb is the power voltage Vdd in the dynamic threshold transistor.

According to the expression (1), it can be understood that the shift amount ΔVt of the threshold value increases and a greater amount of drive current flows as γ increases when the constant voltage Vb is applied to the shallow well region.

The shift amount ΔVt of the threshold value is inversely proportion to the width Xd of the depletion layer that extends from the gate oxide film toward the substrate side.

ΔVt∝ToxVb/Xd (2)

In the above expression, Tox represents the gate insulation film thickness. Therefore, it can be understood that, in order to increase the substrate bias effect according to the expression (2), it is effective to restrain the width Xd of the depletion layer that extends from the gate insulation film toward the substrate side.

The semiconductor device shown in FIG. 14 has a structure that restrains the width Xd of the depletion layer. The depletion layer, which extends from the interfaces between the gate insulation films 351 and 351 and the low impurity concentration regions 327 and 328 to the substrate side, can scarcely enter the high impurity concentration regions 325 and 326. That is, the high impurity concentration regions 325 and 326 play the role of a depletion layer stopper. Therefore, the thickness of the low impurity concentration regions 327 and 328 must be made thinner than the thickness of the depletion layer in the absence of the high impurity concentration regions 325 and 326. In the absence of the high impurity concentration regions 325 and 326, the thickness of the depletion layer when an inversion layer is formed is about 50 nm at an impurity concentration of 5×10¹⁷ cm⁻³. Therefore, the low impurity concentration regions 327 and 328 should preferably have a thickness of not greater than 40 nm so that the high impurity concentration regions 325 and 326 may sufficiently play the role of the depletion layer stopper.

The effect of the increase of γ is estimated here. In, for example, a dynamic threshold transistor of a normal well structure, γ is about 0.2. On the other hand, in the semiconductor device shown in FIG. 14, γ can be set to about 0.5. Assuming that Vb=0.6 V, then ΔVt=−0.12 V when γ=0.2, and ΔVt=−0.30 V when γ=0.5, according to the expression (1). That is, if γ is increased from 0.2 to 0.5, then the absolute value of the shift amount of the threshold value is increased by 0.18 V. Therefore, at same threshold value (the threshold value herein means the threshold value when the substrate bias is 0), the drive current increases as γ increases. Moreover, with same drive current, the threshold value (the threshold value herein means the threshold value when the substrate bias is 0) can be increased if γ is increased. For example, if γ is increased from 0.2 to 0.5, then same drain current can be obtained even if the threshold value (the threshold value herein means the threshold value when the substrate bias is 0) is increased by 0.18 V (the drain current is practically further increased due to a narrowed depletion layer width as a consequence of an increase in the substrate concentration). According to the sub-threshold characteristic of the dynamic threshold transistor at room temperature, drain current is increased by one order of magnitude per gate voltage of 0.06 V. Therefore, if the threshold value (the threshold value herein means the threshold value when the substrate bias is 0) is increased by 0.18 V, then the off-state current is reduced by three orders of magnitude. Consequently, the off-state current can be reduced by increasing γ.

Likewise, assuming that γ=0.3 and Vb=0.6 V, then ΔVt=−0.18 V. Therefore, assuming that the drive current is same, then the off-state current is reduced by one order of magnitude as γ is increased from 0.2 to 0.3. In the semiconductor device shown in FIG. 14, γ changes according to the thickness of the p-type low impurity concentration regions 327 and 328 and the impurity concentration of the high impurity concentration regions 325 and 326. In the dynamic threshold transistor that has the normal well structure, γis about 0.2, and therefore, γ should preferably be not smaller than 0.3 according to the aforementioned results.

It is possible to estimate γ of the dynamic threshold transistor by the following method. The drive current in the normal MOS (MOSFET in which the gate electrode and the shallow well region are not connected with each other), which has the same well impurity profile as that of the dynamic threshold transistor, is assumed to be Icv. In this case, the drive current is the drain current when a voltage of 0 V is applied to the source region and the power voltage Vdd is applied to the gate electrode and the drain electrode in the case of the n-channel type MOSFET. On the other hand, the drive current of the dynamic threshold transistor is assumed to be Idt. These are expressed by the following expressions.

Icv=WμCox(Vdd−Vtc)²/2 L (3)

Idt=WμCox(Vdd−Vtc−ΔVt)²/2 L (4)

γ=−ΔVt/Vdd (5)

In the above expressions, W represents the gate width, μ represents the mobility, Cox represents the electrostatic capacity of the gate insulation film, and Vtc represents the threshold value of the normal MOS. According to the expressions (3) through (5), the following expression results.

Idt/Icv=(1−Vtc/Vdd+γ)²/(1−Vtc/Vdd)² (6)

Since the constituents other than γ are directly measurable quantities, and therefore, γ can be obtained from the expression (6).

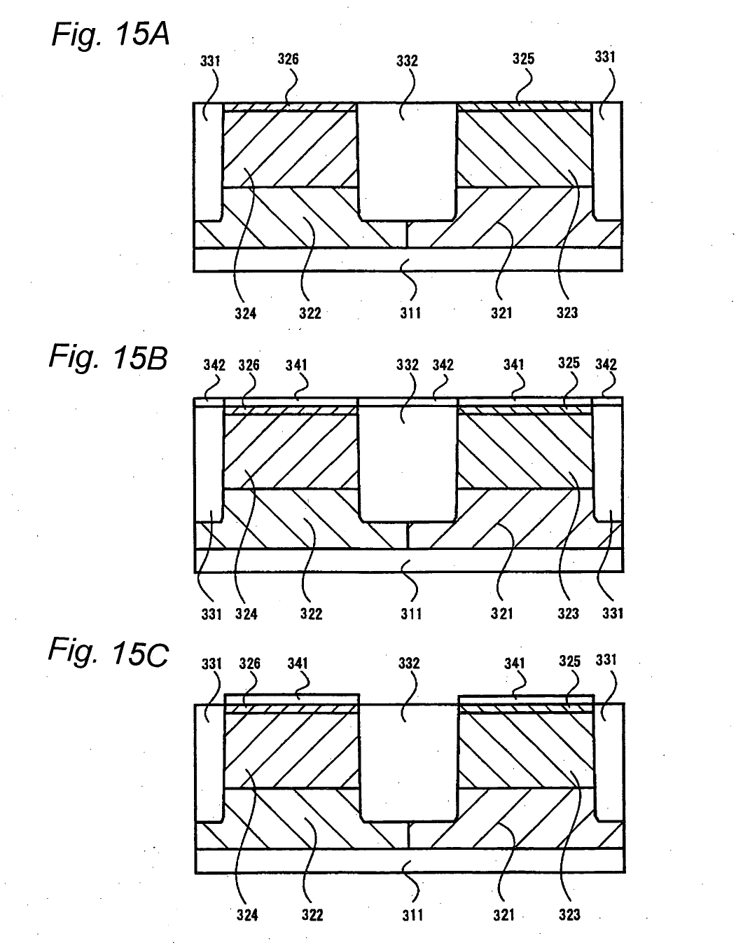

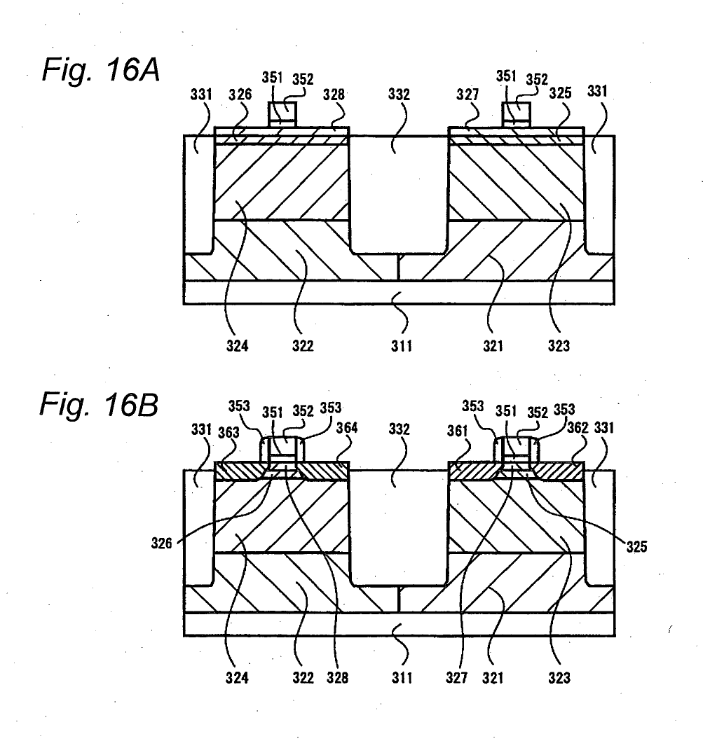

Next, procedures for forming the semiconductor device of the present fifth embodiment will be described with reference to FIGS. 15A through 15C and 16A and 16B.

First of all, as shown in FIG. 15A, the element isolation regions 331 and 332 are formed on the semiconductor substrate 311. The element isolation regions 331 and 332 can be formed by using, for example, the STI (Shallow Trench Isolation) method. If the STI method is used, it is easy to concurrently form element isolation regions of various widths. The depths of the element isolation regions 331 and 332 are set so that the shallow well regions 323 and 324 of mutually adjacent elements are electrically isolated and the deep well regions 321 and 322 are not electrically isolated. The element isolation regions 331 and 332 should preferably have a depth of, for example, 0.2 μm to 2 μm.

Next, the n-type deep well region 321 and the p-type deep well region 322 are formed in the semiconductor substrate 311. As an impurity ion that gives an n-type doping, there can be enumerated ³¹P⁺. For example, when ³¹P⁺ is employed as an impurity ion, there can be provided the condition of an implantation energy of 240 KeV to 1500 KeV and a dosage of 5×10¹¹ cm⁻² to 1×10¹⁴ cm⁻². As an impurity ion that gives a p-type doping, there can be enumerated ¹¹B⁺. For example, when ¹¹B⁺ ion is employed as an impurity ion, there can be provided the condition of an implantation energy of 100 KeV to 1000 KeV and a dosage of 5×10¹¹ cm⁻² to 1×10¹⁴ cm⁻².

Next, the p-type shallow well region 323 and the n-type shallow well region 324 are formed on the deep well regions 321 and 322. As an impurity ion that gives an n-type doping, there can be enumerated ³¹P⁺. For example, when ³¹P⁺ is employed as an impurity ion, formation can be achieved on the condition of an implantation energy of 130 KeV to 900 KeV and a dosage of 5×10¹¹ cm⁻² to 1×10¹⁴ cm⁻². As an impurity ion that gives a p-type doping, there can be enumerated ¹¹B⁺. For example, when ¹¹B⁺ ion is employed as an impurity ion, formation can be achieved on the condition of an implantation energy of 60 KeV to 500 KeV and a dosage of 5×10¹¹ cm⁻² to 1×10¹⁴ cm⁻².

The order of impurity implantation for forming the well region is not limited to the aforementioned order but allowed to be rearranged.

The depth of the junctions between the shallow well regions 323 and 324 and the deep well regions 321 and 322 are determined by the condition of impurity implantation into the shallow well regions 323 and 324, the condition of impurity implantation into the deep well regions 321 and 322 and the thermal process subsequently carried out. The depths of the element isolation regions 331 and 332 are set so that the shallow well regions 323 and 324 of the mutually adjacent elements are electrically isolated and the deep well regions 321 and 322 are not electrically isolated.

Next, as shown in FIG. 15A, an impurity of the same conductive type as that of the shallow well regions 323 and 324 is implanted into the uppermost layer of the shallow well regions 323 and 324 to form the p-type high impurity concentration region 325 and the n-type high impurity concentration region 326. As an impurity ion that gives an n-type doping, there can be enumerated ⁷⁵As⁺. For example, when ⁷⁵As⁺ is employed as an impurity ion, formation can be achieved on the condition of an implantation energy of 3 KeV to 15 KeV and a dosage of 1×10¹² cm⁻² to 1×10¹³ cm⁻². As an impurity ion that gives a p-type doping, there can be enumerated ¹¹⁵In⁺. For example, when ¹¹⁵In⁺ ion is employed as an impurity ion, formation can be achieved on the condition of an implantation energy of 5 KeV to 20 KeV and a dosage of 1×10¹² cm⁻² to 1×10¹³ cm⁻².

There can be employed ³¹P⁺ ion, ¹²²Sb⁺ ion, ¹¹B⁺ ion, ⁴⁹BF₂⁺ ion, decaborane ion and so on besides the aforementioned ⁷⁵As⁺ ion and ¹¹⁵In⁺ ion as an impurity ion for the formation of the high impurity concentration regions 325 and 326.

Next, as shown in FIG. 15B, a monocrystalline silicon film 341, which succeeds the orientation of the silicon substrate, is selectively epitaxially grown only in the exposed active region of the silicon substrate, and a polysilicon film 342 is grown on other regions. That is, the monocrystalline silicon film 341 is formed on the active region, and the polysilicon film 342 is formed on the element isolation regions 331 and 332. The thickness of the monocrystalline silicon film 341 can be set to, for example, 8 nm to 50 nm. The selective epitaxial growth can be achieved by the following method. If the surface of the silicon substrate is cleaned by HF (Hydrofluoric Acid) treatment and thereafter a silicon film is deposited on the condition of, for example, a temperature of 580° C. to 680° C. and Si₂H₆ or SiH₄ gas of 20 Pa to 100 Pa by the LPCVD (Low-Pressure Chemical Vapor Deposition) method, then it is possible to form a monocrystalline silicon film on the active region and form a polysilicon film on the other regions. When forming the silicon films, it is most desirable not to introduce a gas including an impurity that gives a conductive type doping.

Next, as shown in FIG. 15C, the polysilicon film 342 is selectively etched by a mixed liquid of hydrofluoric acid, nitric acid and acetic acid. As described above, the method of forming the monocrystalline silicon film on the active region, forming the polysilicon film on the other regions and etching only the polysilicon has an advantage that the effect of preventing silicon from remaining on the element isolation region.

The process of forming the monocrystalline silicon film on the active region and forming the polysilicon film on the other regions and the process of selectively etching the polysilicon film can be replaced by another process. That is, by selectively epitaxially growing the monocrystalline silicon film only on the active region in the state of FIG. 15A, the state of FIG. 15C can be directly provided without carrying out etching. According to this method, the monocrystalline silicon film can be formed only on the active region through a fewer processes.

Next, as shown in FIG. 16A, the gate insulation films 351 and the gate electrode 352 are formed on the monocrystalline silicon film 341. By heat treatment at this time, impurities diffuse from the high impurity concentration regions 325 and 326 into the monocrystalline silicon film 341, providing the p-type low impurity concentration region 327 and the n-type low impurity concentration region 328, respectively.

Next, as shown in FIG. 16B, the source regions 361 and 363 and the drain regions 362 and 364 are formed. At this time, it is acceptable to form an LDD (Lightly Doped Drain) region by a well-known method by utilizing the gate sidewall insulation film 353.

It is to be noted that a method for connecting the gate electrode with the shallow well region indispensable for forming a dynamic threshold transistor is disclosed in Japanese Unexamined Patent Application No. H10-22462.

Subsequently, impurity activation annealing is carried out. The activation annealing is carried out on condition that the impurities are sufficiently activated and the impurities do not excessively diffuse. For example, it is possible to carry out the annealing at a temperature of 800° C. to 1000° C. for 10 to 100 seconds.

Subsequently, by forming interconnections and so on by a well-known technique, a CMOS circuit can be constructed for the formation of a semiconductor device.

A MOSFET of the normal structure may exist in mixture besides the dynamic threshold transistors. In this case, in the element to be provided by a normal MOSFET, it is proper to fix the potential of the shallow well region without connecting the gate electrode with the shallow well region.

According to the aforementioned manufacturing method, the high impurity concentration region is preliminarily formed in the uppermost layer portion of the shallow well region, and the monocrystalline silicon film is subsequently epitaxially grown. Therefore, the low impurity concentration regions 327 and 328 and the high impurity concentration regions 325 and 326 can be formed successively in the depthwise direction from the front surface side so as to have a steep profile that can be hardly provided by ion implantation. Moreover, the film grown on the active region is the monocrystalline silicon that succeeds the azimuth of the substrate crystal. Therefore, no additional thermal process for carrying out recrystallization is needed, and a steep profile can be formed. Therefore, a CMOS circuit constructed of the dynamic threshold transistors of a remarkable substrate bias effect can be formed.

According to the semiconductor device of the present embodiment, the low impurity concentration regions 327 and 328 are formed just under the gate insulation films 351 and 351 of the dynamic threshold transistors 4 and 5, and the high impurity concentration regions 325 and 326 are further formed under the regions. The low impurity concentration regions 327 and 328 have a thickness smaller than the width of the gate depletion layer formed of the dynamic threshold transistor that have a normal impurity profile, and therefore, the width of the depletion layer, which extends from the gate insulation film toward the shallow well region side, is restrained. Consequently, the substrate bias effect is increased, and therefore, the off-state current can be reduced by raising the threshold values of the dynamic threshold transistors. Therefore, the semiconductor device, which is constructed of the CMOS circuit of the dynamic threshold transistors, is allowed to have low power consumption with the operating speed kept at high speed.

### SIXTH EMBODIMENT

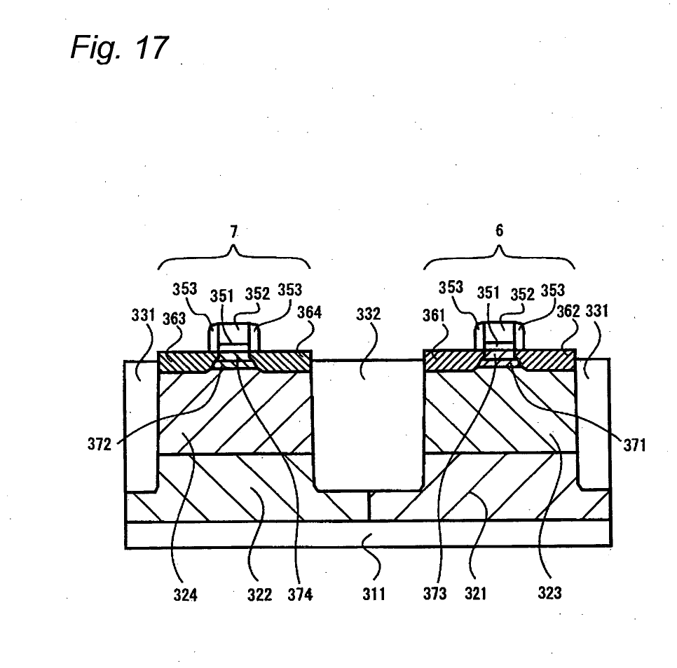

The semiconductor device of the present sixth embodiment shows another method for raising the threshold value for obtaining the desired drain current by increasing the substrate bias effect of dynamic threshold transistors and consequently reducing the off-state current in a CMOS circuit constructed of the dynamic threshold transistors. The semiconductor device of the present sixth embodiment will be described with reference to FIG. 17.

The semiconductor device of the present sixth embodiment differs from the semiconductor device of the fifth embodiment only in the impurity profile just under the gate insulation film. That is, the present sixth embodiment adopts a so-called counter dope structure in which a channel region just under the gate insulation film is doped with an impurity of a conductive type different from the conductive type of the well region.

An n-type low impurity concentration region 373 is formed just under the gate insulation film 351 of an n-channel type dynamic threshold transistor 6, and an n-type high impurity concentration region 371 is further formed under the region. On the other hand, a p-type low impurity concentration region 374 is formed just under the gate insulation film 351 of a p-channel type dynamic threshold transistor 7, and a p-type high impurity concentration region 372 is further formed under the region. The low impurity concentration regions 373 and 374 are allowed to have a thickness of, for example, 5 nm to 10 nm and an impurity concentration of 5×10¹⁶ cm⁻³ to 2×10¹⁷ cm⁻³. Moreover, the high impurity concentration regions 371 and 372 are allowed to have a thickness of, for example, 5 nm to 15 nm and an impurity concentration of 1×10¹⁷ cm⁻³ to 2×10¹⁸ cm⁻³.

Even with the semiconductor device of the present embodiment, the gate depletion layer width can be restrained. Furthermore, since y can be increased up to about 0.8 to 1.0, the substrate bias effect can be increased further than in the semiconductor device of the fifth embodiment. Therefore, a semiconductor device, which is constructed of a CMOS circuit of dynamic threshold transistors and able to operate at high speed with lower power consumption is provided.

### SEVENTH EMBODIMENT

If the merits of the semiconductor device of the fourth embodiment and the semiconductor device of the fifth or sixth embodiment are combined with each other, there is provided a semiconductor device that is constructed of a CMOS circuit of dynamic threshold transistors and has further reduced power consumption.

In the semiconductor device of the fourth embodiment, the gate current is reduced by lowering the power voltage in the standby stage. However, in, for example, the example of FIG. 11, the off-state current dominates contributions to the leak current in the region where the power voltage becomes equal to or lower than 0.4 V. Therefore, it is proper to raise the threshold value in order to further reduce the leak current, but the drive current is reduced to disadvantageously reduce the operating speed of the circuit if the measure is adopted.

Accordingly, if the semiconductor device of the fifth or sixth embodiment is employed, the threshold value can be raised with the drive current of the dynamic threshold transistor maintained by virtue of the increase of the substrate bias effect, and therefore, the off-leak current can be reduced. When the circuit is in the standby stage, it is effective to reduce the gate current by further lowering the power voltage by that much. Therefore, a semiconductor device, which is constructed of a CMOS circuit of dynamic threshold transistors, is allowed to have further reduced power consumption with the operating speed kept at high speed.

### EIGHTH EMBODIMENT

The semiconductor device of any one of the fourth through seventh embodiments can be employed for a static random access memory (SRAM). The SRAM, which has been able to operate at high speed, has had a problem of a leak current in the standby stage because it is a nonvolatile memory.

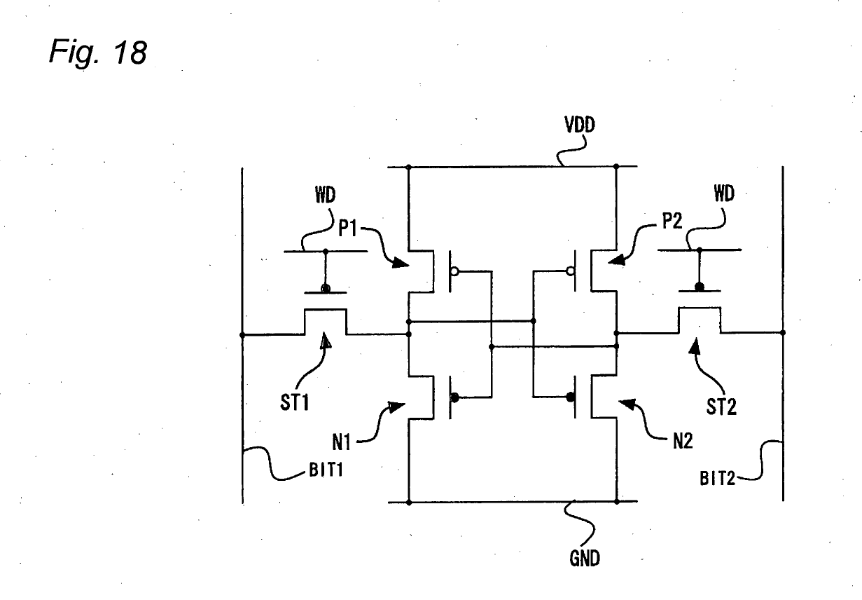

FIG. 18 is a circuit diagram of the SRAM of the present eighth embodiment. There are shown n-channel type dynamic threshold transistors N1, N2, ST1 and ST2 and p-channel type dynamic threshold transistors P1 and P2. There are also shown a word line WD, a first bit line BIT1, a second bit line BIT2, a power line VDD and a grounding line GND.

A pair of N1 and P1 and a pair of N2 and P2 constitute respective complementary inverter circuits, and the two inverter circuits constitute a flip-flop circuit. Moreover, ST1 and ST2 constitute select transistors. When the SRAM is constructed of dynamic threshold transistors, by employing the semiconductor device of any one of the fourth through seventh embodiments, the leak current in the standby stage can be reduced. Therefore, the static random access memory is allowed to have low power consumption with the operating speed thereof kept at high speed.

### NINTH EMBODIMENT

The semiconductor device of any one of the fourth through eighth embodiments can be employed for battery-operated portable electronic equipment of, in particular, portable information terminal. As portable electronic equipment, there can be enumerated portable information terminals, a mobile phone, a game machine and so on.

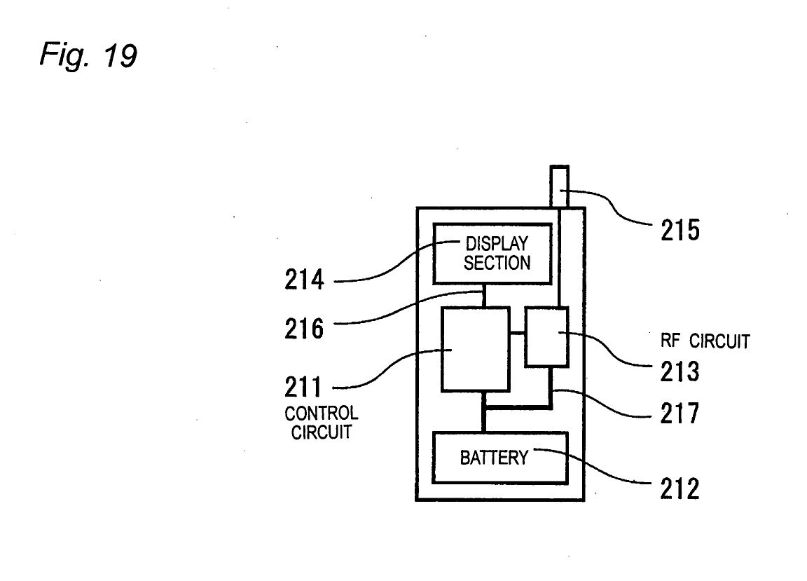

FIG. 19 shows an example of the mobile phone. A control circuit 211 has the semiconductor device of the present invention built-in. The control circuit 211 may be constituted of an LSI (Large Scale Integration) circuit in which a logic circuit constructed of the semiconductor device of the present invention and a memory are consolidated. There are shown a battery 212, an RF (Radio Frequency) circuit section 213, a display section 214, an antenna section 215, a signal line 216 and a power line 217.

By employing the semiconductor device of the present invention for portable electronic equipment, the power consumption of the LSI section can be remarkably reduced with the function and the operating speed of the portable electronic equipment maintained. With this arrangement, the battery life can be remarkably extended.

1. A static random access memory device comprising:
a semiconductor substrate that has an element isolation region and an active region;
a gate electrode provided via a gate insulation film on the semiconductor substrate;
a gate electrode sidewall insulation film provided on at least part of a sidewall of the gate electrode; and
a gate electrode sidewall conductive film that is provided on at least part of a sidewall of the gate electrode sidewall insulation film and provided over a plurality of active regions segmented by the element isolation region.

2. The static random access memory device as claimed in claim 1, wherein the semiconductor substrate is comprised of a SOI substrate.

3. A static random access memory device comprising:
a semiconductor substrate that has an element isolation region and an active region;
a first conductive type deep well region formed in the semiconductor substrate;
a second conductive type shallow well region formed in the first conductive type deep well region;
a gate electrode provided via a gate insulation film on the semiconductor substrate;
a gate electrode sidewall insulation film provided on at least part of a sidewall of the gate electrode; and
a gate electrode sidewall conductive film that is provided on at least part of a sidewall of the gate electrode sidewall insulation film and provided over a plurality of active regions segmented by the element isolation region,
at least part of the gate electrode constituting a first conductive type dynamic threshold transistor by being electrically connected to the second conductive type shallow well region, and
the second conductive type shallow well region being electrically isolated by the element isolation region.

4. A static random access memory device comprising:
a semiconductor substrate that has an element isolation region and an active region;
a first conductive type deep well region formed in the semiconductor substrate;
a second conductive type shallow well region formed in the first conductive type deep well region;
a gate electrode provided via a gate insulation film on the semiconductor substrate;
a gate electrode sidewall insulation film provided on at least part of a sidewall of the gate electrode; and
a gate electrode sidewall conductive film that is provided on at least part of a sidewall of the gate electrode sidewall insulation film and provided over a plurality of active regions segmented by the element isolation region,
at least part of the gate electrode constituting a first conductive type dynamic threshold transistor by being electrically connected to the second conductive type shallow well region,
the element isolation region being comprised of a shallow element isolation region and a deep element isolation region, and
the second conductive type shallow well region being electrically isolated by the deep element isolation region.

5. A static random access memory device comprising:
a SOI semiconductor substrate that has an element isolation region and an active region;
a gate electrode provided via a gate insulation film on the SOI semiconductor substrate;
a gate electrode sidewall insulation film provided on at least part of a sidewall of the gate electrode; and
a gate electrode sidewall conductive film that is provided on at least part of a sidewall of the gate electrode sidewall insulation film and provided over a plurality of active regions segmented by the element isolation region,
at least part of the gate electrode constituting a first conductive type dynamic threshold transistor by being electrically connected to the second conductive type body region of the SOI semiconductor substrate.

6. The static random access memory device as claimed in claim 3 on, wherein
a first conductive type shallow well region is formed in the first conductive type deep well region, the deep well region and the shallow well region of the first conductive type integrally constituting a first conductive type well region,
the static random access memory device is a six-element type comprising:
two second conductive type field-effect transistors that constitute a flip-flop circuit formed on the first conductive type well region;
two first conductive type field-effect transistors that constitute a flip-flop circuit formed on the second conductive type shallow well region; and
two first conductive type field-effect transistors that serve as transfer gate transistors formed on the second conductive type shallow well region, and
only the four first conductive type field-effect transistors are the dynamic threshold transistors.

7. The static random access memory device as claimed in claim 6, wherein the first conductive type is n-type.

8. The static random access memory device as claimed in claim 1, wherein the gate electrode sidewall conductive film is comprised of a polycrystalline semiconductor film.

9. A static random access memory device manufacturing method comprising the steps of:
forming a gate insulation film on a semiconductor substrate;
forming a first conductive film on at least the gate insulation film;
forming a first conductive film pattern by processing the first conductive film into a prescribed pattern;
forming a sidewall insulation film on at least part of a sidewall of the first conductive film pattern;
forming a sidewall conductive film comprised of the second conductive film via the sidewall insulation film on a sidewall of the first conductive film pattern by depositing the second conductive film on the semiconductor substrate and etching the second conductive film; and
forming a layer that serves as a gate electrode, a layer that serves as a source region, a layer that serves as a drain region and an interconnection that is comprised of a stack type diffusion layer by processing the first conductive film pattern and the sidewall conductive film so as to remove part of the first conductive film pattern and part of the sidewall conductive film by anisotropic etching that has selectivity to the sidewall insulation film.

10. A semiconductor device comprising:
a complementary type circuit comprised of a plurality of dynamic threshold transistors in which a well region segmented every element by an element isolation region is electrically connected with a gate electrode, the complementary type circuit comprising at least two modes of:
an active mode in which the complementary type circuit is operated at high speed; and
a standby mode in which the complementary type circuit is operated at low speed or its operation is stopped, and
when the complementary type circuit is in the standby mode, the complementary type circuit being supplied with a power voltage lower than when the complementary type circuit is in the active mode.

11. The semiconductor device as claimed in claim 10, wherein,
when the complementary type circuit is in the standby mode,
the dynamic threshold transistor that constitutes the complementary type circuit has a gate current value that is not greater than an off-state current value of the dynamic threshold transistor.

12. The semiconductor device as claimed in claim 10, wherein
the complementary type circuit is divided into a plurality of basic circuit blocks, and
the basic circuit blocks can be independently put into the active mode or the standby mode.

13. A semiconductor device comprising:
a semiconductor substrate;
an element isolation region;
deep well regions of a first conductive type and a second conductive type, the regions being formed in the semiconductor substrate;
shallow well regions of the second conductive type and the first conductive type, the regions being formed respectively in the deep well regions of the first conductive type and the second conductive type; and
a plurality of gate electrodes formed via a gate insulation film on the shallow well regions of the second conductive type and the first conductive type,
the plurality of gate electrodes being electrically connected to the shallow well region of the second conductive type or the first conductive type, constituting dynamic threshold transistors of the first conductive type and the second conductive type, respectively,
the shallow well regions of the second conductive type and the first conductive type being electrically isolated by the element isolation region every one of the dynamic threshold transistors,
the second conductive type shallow well region having therein a low impurity concentration layer of the second conductive type and a high impurity concentration layer of the second conductive type, which are formed successively in a depthwise direction from an interface side with the gate insulation film,
the first conductive type shallow well region having therein a low impurity concentration layer of the first conductive type and a high impurity concentration layer of the first conductive type, which are formed successively in the depthwise direction from the interface side with the gate insulation film,
the low impurity concentration layers of the second conductive type and the first conductive type having a thickness of not greater than 40 nm, and
the dynamic threshold transistors of the first conductive type and the second conductive type constituting a complementary type circuit.

14. A method for manufacturing the semiconductor device claimed in claim 13, at least comprising, after a process for forming the element isolation region, the steps of:
forming high impurity concentration regions of the second conductive type and the first conductive type in an uppermost layer portion of an active region defined as a region in which the element isolation region does not exist on the semiconductor substrate;
carrying out a process for depositing a semiconductor film all over a surface under condition that a monocrystalline semiconductor film is epitaxially grown selectively on the active region, and a polycrystalline semiconductor film is grown on a region other than the active region; and
removing the polycrystalline semiconductor selectively with respect to the monocrystalline semiconductor film.

15. A method for manufacturing the semiconductor device claimed in claim 13, at least comprising, after a process for forming at least the element isolation region, the steps of:
forming high impurity concentration regions of the second conductive type and the first conductive type in an uppermost layer portion of an active region defined as a region in which the element isolation region does not exist on the semiconductor substrate; and
epitaxially growing a monocrystalline semiconductor film selectively only in the active region.

16. A semiconductor device comprising:
a semiconductor substrate;
an element isolation region;
deep well regions of a first conductive type and a second conductive type, the regions being formed in the semiconductor substrate;
shallow well regions of the second conductive type and the first conductive type, the regions being formed respectively in the deep well regions of the first conductive type and the second conductive type; and
a plurality of gate electrodes formed via a gate insulation film on the shallow well regions of the second conductive type and the first conductive type,
the plurality of gate electrodes being electrically connected to the shallow well region of the second conductive type or the first conductive type, constituting dynamic threshold transistors of the first conductive type and the second conductive type, respectively,
the shallow well regions of the second conductive type and the first conductive type being electrically isolated by the element isolation region every one of the dynamic threshold transistors,
the second conductive type shallow well region having thereon a low impurity concentration layer of the first conductive type and a high impurity concentration layer of the first conductive type, which are formed successively in a depthwise direction from an interface side with the gate insulation film,
the first conductive type shallow well region having thereon a low impurity concentration layer of the second conductive type and a high impurity concentration layer of the second conductive type, which are formed successively in the depthwise direction from the interface side with the gate insulation film, and
the dynamic threshold transistors of the first conductive type and the second conductive type constituting a complementary type circuit.

17. A semiconductor device comprising:
a complementary type circuit comprised of a plurality of dynamic threshold transistors in which a well region segmented every element by an element isolation region is electrically connected with a gate electrode,
the plurality of dynamic threshold transistors having a substrate bias effect factor y of not smaller than 0.3.

18. The semiconductor device as claimed in claim 13,
the complementary type circuit comprising at least two modes of:
an active mode in which the complementary type circuit is operated at high speed; and
a standby mode in which the complementary type circuit is operated at low speed or its operation is stopped, and
when the complementary type circuit is in the standby mode, the complementary type circuit being supplied with a power voltage lower than when the complementary type circuit is in the active mode.

19. A static random access memory device equipped with the semiconductor device claimed in claim 10.

20. Portable electronic equipment equipped with the semiconductor device claimed in claim 10.

21. Portable electronic equipment equipped with the static random access memory device claimed in claim 19.
